(19) United States
(12) Patent Application Publication
(10) Pub. No.: US 2026/0004820 A1
(43) Pub. Date: Jan. 1, 2026

(54) SEMICONDUCTOR DEVICE AND DATA STORAGE SYSTEM INCLUDING THE SAME

(71) Applicant: Samsung Electronics Co., Ltd., Suwon-si (KR)

(72) Inventors: Yewon Shin, Suwon-si (KR); Dongkyu Kim, Suwon-si (KR); Jonghyuk Kim, Suwon-si (KR); Jaesun Yun, Suwon-si (KR); Hyunsook Yoon, Suwon-si (KR)

(21) Appl. No.: 19/085,190

(22) Filed: Mar. 20, 2025

(30) Foreign Application Priority Data
Jun. 27, 2024 (KR) 10-2024-0084629

(51) Int. Cl. G11C 5/06; H01L 25/065; H10B 43/35; H10B 43/40; H10B 80/00

(52) U.S. Cl. CPC G11C 5/063; H01L 25/0657; H10B 43/35; H10B 43/40; H10B 80/00; H01L 2225/06506; H01L 2225/0651

(57) ABSTRACT

A semiconductor device includes a lower structure and an upper structure. The upper structure includes an inter-metal insulating layer, a first upper conductive via, upper conductive patterns, and a capping insulating structure. The upper conductive patterns include a first input/output interconnection line and a first barrier structure. The first input/output interconnection line includes a first connection region and a first pad region. The first connection region includes a first side surface, a second side surface, and a third side surface that extends from ends of the first side surface and the second side surface. The first barrier structure includes a first internal barrier structure and an external barrier structure. The first internal barrier structure includes a first internal line portion, a second internal line portion, and a third internal portion.

### CROSS-REFERENCE TO RELATED APPLICATION(S)

This application claims benefit of priority to Korean Patent Application No. 10-2024-0084629 filed on Jun. 27, 2024, in the Korean Intellectual Property Office, the disclosure of which is incorporated herein by reference in its entirety.

### TECHNICAL FIELD

The present disclosure relates to a semiconductor device and a data storage system including the same.

### BACKGROUND

There is a demand for a semiconductor device capable of storing high-capacity data in an electronic system requiring data storage. Accordingly, a method capable of increasing the data storage capacity of a semiconductor device has been researched. For example, as one of the methods for increasing the data storage capacity of the semiconductor device, a semiconductor device including three-dimensionally arranged memory cells instead of two-dimensionally arranged memory cells has been proposed.

### SUMMARY

An aspect of the present disclosure is to provide a semiconductor device that may improve reliability thereof.

An aspect of the present disclosure is to provide a data storage system including the semiconductor device.

Provided is a semiconductor device according to example embodiments of the present disclosure. The semiconductor device includes: a lower structure including a memory region that includes memory cells and a peripheral region that includes a peripheral circuit, and an upper structure on the lower structure. The upper structure includes an inter-metal insulating layer on the lower structure, a first upper conductive via that extends into the inter-metal insulating layer, upper conductive patterns on the inter-metal insulating layer, and a capping insulating structure on the inter-metal insulating layer and the upper conductive patterns. The upper conductive patterns include a first input/output interconnection line that is on the inter-metal insulating layer and is in contact with an upper surface of the first upper conductive via, and a first barrier structure that is on the inter-metal insulating layer and is electrically insulated from the first upper conductive via and the first input/output interconnection line. The first input/output interconnection line includes a first connection region that is adjacent to the first barrier structure, has a line shape that extends in a first direction that is parallel to an upper surface of the upper structure, and is in contact with the upper surface of the first upper conductive via a first interconnection line region that extends from the first connection region, and a first pad region that extends from the first interconnection line region. In plan view, the first connection region includes a first side surface, a second side surface that opposes the first side surface in a second direction that is perpendicular to the first direction, and a third side surface that extends from ends of the first side surface and the second side surface. The first barrier structure includes: a first internal barrier structure adjacent to the first connection region, and an external barrier structure that is adjacent to the first internal barrier structure and includes at least two external line portions that are parallel with each other. The first internal barrier structure includes: a first internal line portion that faces the first side surface of the first connection region, a second internal line portion that faces the second side surface of the first connection region, and a third internal portion that extends from the first internal line portion and the second internal line portion and faces the third side surface of the first connection region.

Provided is a semiconductor device according to example embodiments of the present disclosure. The semiconductor device includes: a lower structure including a memory region that includes memory cells and a peripheral region that includes a peripheral circuit, and an upper structure on the lower structure. The upper structure includes an inter-metal insulating layer on the lower structure, a first upper conductive via that extends into the inter-metal insulating layer, upper conductive patterns on the inter-metal insulating layer, and a capping insulating structure on the inter-metal insulating layer and the upper conductive patterns. The upper conductive patterns include a first input/output interconnection line that is on the inter-metal insulating layer and is in contact with an upper surface of the first upper conductive via, and a power interconnection line that is on the inter-metal insulating layer and is adjacent to the first input/output interconnection line. The power interconnection line includes a first side surface that faces the first input/output interconnection line, a second side surface that faces the first side surface, and at least one opening that is adjacent to the first side surface. In plan view, the first side surface is between a portion of the first input/output interconnection line that is connected to the first upper conductive via and the at least one opening are sequentially arranged in a first direction that is perpendicular to the first side surface.

Provided is a data storage system according to example embodiments of the present disclosure. The data storage system includes: a semiconductor device including an input/output pad, and a controller electrically connected to the semiconductor device through the input/output pad and configured to control the semiconductor device. The semiconductor device includes a lower structure including a memory region that includes memory cells and a peripheral region that includes a peripheral circuit, and an upper structure on the lower structure. The upper structure includes an inter-metal insulating layer on the lower structure, a first upper conductive via that extends into the inter-metal insulating layer, upper conductive patterns on the inter-metal insulating layer, and a capping insulating structure on the inter-metal insulating layer and the upper conductive patterns. The upper conductive patterns include a first input/output interconnection line that is on the inter-metal insulating layer and is in contact with an upper surface of the first upper conductive via, and a first barrier structure that is on the inter-metal insulating layer and is electrically insulated from the first upper conductive via and the first input/output interconnection line. The first input/output interconnection line that includes a first connection region that is adjacent to the first barrier structure, has a line shape that extends in a first direction that is parallel to an upper surface of the upper structure, and is in contact with the upper surface of the first upper conductive via, and a first interconnection line region that extends from the first connection region. In plan view, the first connection region includes a first side surface, a second side surface that opposes the first side surface in a second direction that is perpendicular to the first direction, and a third side surface that extends from ends of the first side surface and the second side surface. The first barrier structure includes a first internal barrier structure adjacent to the first connection region, and an external barrier structure that is adjacent to the first internal barrier structure and includes at least two external line portions that are parallel with each other. The first internal barrier structure includes a first internal line portion that faces the first side surface of the first connection region, a second internal line portion that faces the second side surface of the first connection region, and a third internal portion that extends from the first internal line portion and the second internal line portion and faces the third side surface of the first connection region.

### BRIEF DESCRIPTION OF DRAWINGS

The above and other aspects, features, and advantages of the present disclosure will be more clearly understood from the following detailed description, taken in conjunction with the accompanying drawings, in which:

FIGS. 1 to 4 are views illustrating semiconductor devices according to example embodiments of the present disclosure;

FIGS. 5A, 5B, 5C, 5D 6A, and 6B are views illustrating examples of a semiconductor device according to example embodiments of the present disclosure;

FIGS. 7A and 7B are partially enlarged cross-sectional views illustrating a semiconductor device according to example embodiments of the present disclosure;

FIG. 8A is a partially enlarged cross-sectional view illustrating a semiconductor device according to example embodiments of the present disclosure;

FIG. 8B is a partially enlarged cross-sectional view illustrating a semiconductor device according to example embodiments of the present disclosure;

FIG. 8C is a partially enlarged cross-sectional view illustrating a semiconductor device according to example embodiments of the present disclosure;

FIG. 9A is a partially enlarged plan view illustrating a semiconductor device according to example embodiments of the present disclosure;

FIG. 9B is a partially enlarged plan view illustrating a semiconductor device according to example embodiments of the present disclosure;

FIG. 9C is a partially enlarged plan view illustrating a semiconductor device according to example embodiments of the present disclosure;

FIG. 9D is a partially enlarged plan view illustrating a semiconductor device according to example embodiments of the present disclosure;

FIG. 9E is a partially enlarged plan view illustrating a semiconductor device according to example embodiments of the present disclosure;

FIG. 9F is a partially enlarged plan view illustrating a semiconductor device according to example embodiments of the present disclosure;

FIG. 10 is a partially enlarged plan view illustrating a semiconductor device according to example embodiments of the present disclosure;

FIG. 11 is a partially enlarged plan view illustrating a semiconductor device according to example embodiments of the present disclosure;

FIG. 12 is a partially enlarged plan view illustrating a semiconductor device according to example embodiments of the present disclosure;

FIG. 13A is a partially enlarged plan view illustrating a semiconductor device according to example embodiments of the present disclosure;

FIG. 13B is a partially enlarged plan view illustrating a semiconductor device according to example embodiments of the present disclosure;

FIG. 13C is a partially enlarged plan view illustrating a semiconductor device according to example embodiments of the present disclosure;

FIG. 13D is a partially enlarged plan view illustrating a semiconductor device according to example embodiments of the present disclosure;

FIG. 13E is a partially enlarged plan view illustrating a semiconductor device according to example embodiments of the present disclosure;

FIG. 14A is a partially enlarged plan view illustrating a semiconductor device according to example embodiments of the present disclosure;

FIG. 14B is a partially enlarged plan view illustrating a semiconductor device according to example embodiments of the present disclosure; and

FIGS. 15A and 15B are views illustrating a semiconductor device according to example embodiments of the present disclosure.

### DETAILED DESCRIPTION

Hereinafter, example embodiments of the present disclosure will be described with reference to the accompanying drawings.

Hereinafter, terms such as “upper,” “intermediate,” “lower,” “internal,” and “external” may be replaced with other terms, such as “first,” “second,” and “third,” and may be used to describe the components of the specification. Although the terms such as “first,” “second,” and “third” may be used to describe various components, the components are not limited by the terms, and the “first element” may be referred to as a “second element” or may be referred to as other terms that may be distinguished from other components.

Even if a size ratio, a width ratio and a length ratio between the components illustrated in the drawing are not described separately, they may be understood from the components illustrated in the drawings.

To clarify the present disclosure, the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the singular forms “a,” “an” and “the” are intended to include the plural forms as well, unless the context clearly indicates otherwise. The term “and/or” includes any and all combinations of one or more of the associated listed items. The term “connected” may be used herein to refer to a physical and/or electrical connection and may refer to a direct or indirect physical and/or electrical connection. The term “exposed” may be used to define a relationship between particular layers or surfaces, but it does not require the layer or surface to be free of other elements or layers thereon in the completed device.

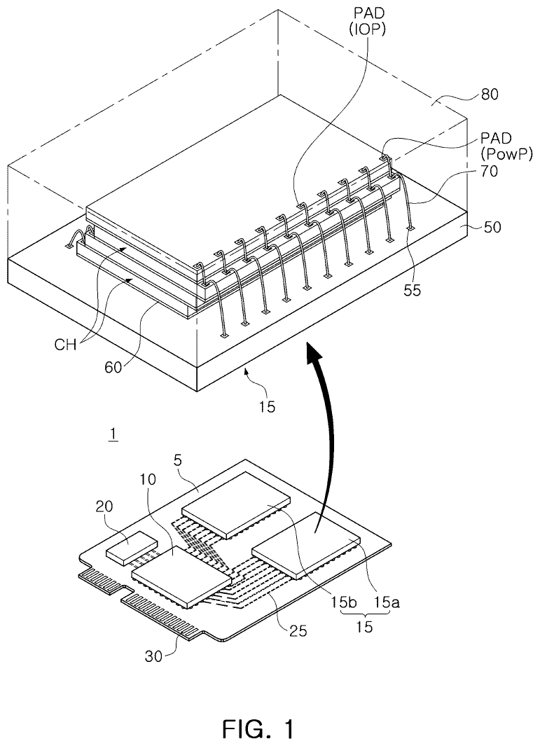

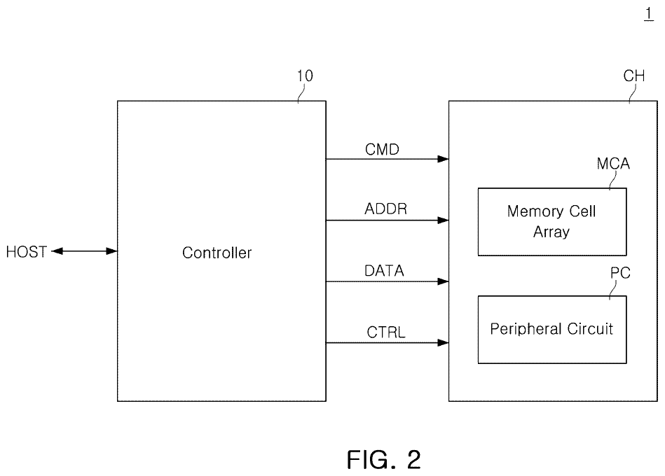

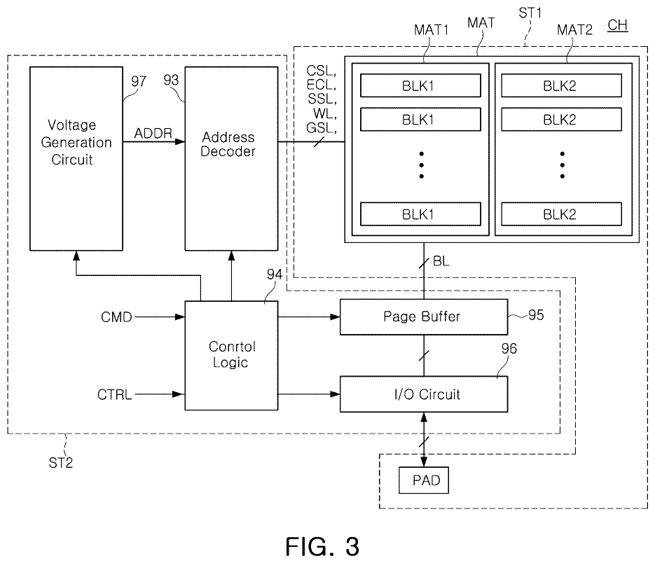

Referring to FIGS. 1 to 3, semiconductor devices according to embodiments of the present disclosure will be described. Referring to FIGS. 1 to 3, FIG. 1 is a perspective view schematically illustrating a data storage system including a semiconductor device according to example embodiments of the present disclosure, FIG. 2 is a schematic block diagram of a data storage system including a semiconductor device according to example embodiments of the present disclosure, and FIG. 3 is a block diagram schematically illustrating a semiconductor device according to example embodiments of the present disclosure.

First, referring to FIG. 1, a data storage system 1 according to example embodiments may include a main board 5, a controller 10 mounted on the main board 5, one or more semiconductor packages 15, and a DRAM 20. The semiconductor package 15 and the DRAM 20 may be connected to the controller 10 by interconnection line patterns 25 formed on the main board 5.

The main board 5 may include a connector 30 including a plurality of pins coupled with an external host (HOST of FIG. 1C). The number and arrangement of the plurality of pins in the connector 30 may vary depending on a communication interface between the data storage system 1 and the external host HOST.

In example embodiments, the data storage system 1 may communicate with an external host according to any one of interfaces such as Universal Serial Bus (USB), Peripheral Component Interconnect Express (PCI-Express), Serial Advanced Technology Attachment (SATA), M-Phy for Universal Flash Storage (UFS), and the like.

In example embodiments, the data storage system 1 may be operated by power supplied from the external host (HOST of FIG. 2) through the connector 30.

The data storage system 1 may further include a Power Management Integrated Circuit (PMIC) distributing power supplied from the external host HOST to the controller 10 and the semiconductor package 15.

The controller 10 may write data to the semiconductor package 15 or read data from the semiconductor package 15, and may improve operating speed of the data storage system 1.

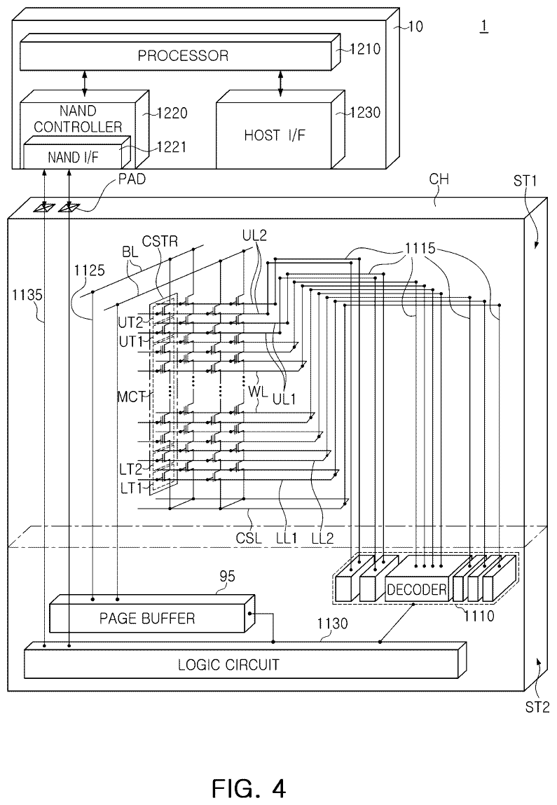

The DRAM 20 may be a buffer memory for alleviating a speed difference between the semiconductor package 15, a data storage space, and an external host. The DRAM 20 included in the data storage system 1 may also operate as a type of cache memory, and may provide a space for temporarily storing data in a control operation for the semiconductor package 15. When the DRAM 20 is included in the data storage system 1, the controller 10 may further include a DRAM controller for controlling the DRAM 20 in addition to a NAND controller 1220 (see FIG. 4) for controlling the semiconductor package 15.

The semiconductor package 15 may include first and second semiconductor packages 15a and 15b spaced apart from each other. Each of the first and second semiconductor packages 15a and 15b may be a semiconductor package including a plurality of semiconductor devices CH. The semiconductor devices CH may also be referred to as semiconductor chips.

Each of the first and second semiconductor packages 15a and 15b may include a package substrate 50, the semiconductor devices CH on the package substrate 50, adhesive layers 60 disposed on lower surfaces of each of the semiconductor devices CH, a connection structure 70 electrically connecting the semiconductor devices CH and the package substrate 50, and a molding layer 80 covering or overlapping the semiconductor devices CH and the connection structure 70 on the package substrate 50.

The package substrate 50 may be a printed circuit board including package upper pads 55. Each of the semiconductor devices CH may include pad patterns PAD. The pad patterns PAD may include an input/output pad IOP and power pads PowP. The power pads PowP may include VDD pads and GND pads.

In example embodiments, the connection structure 70 may be bonding wires electrically connecting the pad patterns PAD and the package upper pads 55. Accordingly, in each of the first and second semiconductor packages 15a and 15b, the semiconductor devices CH may be electrically connected to each other in a bonding wire manner and may be electrically connected to the package upper pads 55 of the package substrate 50. According to example embodiments, in each of the first and second semiconductor packages 15a and 15b, the semiconductor devices CH may be electrically connected to each other by a connection structure including a through-silicon via (TSV), instead of the connection structure 70 in the bonding wire manner.

In example embodiments, the controller 10 and the semiconductor devices CH may be included in one package. For example, the controller 10 and the semiconductor devices CH may be mounted on a separate interposer substrate different from the main substrate 5, and the controller 10 and the semiconductor devices CH may be connected to each other by interconnection lines formed on the interposer substrate.

Next, referring to FIG. 1, FIG. 2 and FIG. 3, the controller 10 may write data DATA to the semiconductor device CH, or read data DATA stored in the semiconductor device CH. In order to write data DATA to the semiconductor device CH, the controller 10 may transmit a command CMD, an address ADDR, a control signal CTRL, and data DATA to the semiconductor devices CH. In order to read data DATA stored in the semiconductor device CH, the controller 10 may transmit the command CMD, the address ADDR, and the control signal CTRL to the semiconductor device CH.

The semiconductor device CH may include nonvolatile memory devices such as a NAND flash memory, a phase change memory (PRAM), a resistive memory (ReRAM), a magneto-resistive memory (MRAM), or a ferroelectric memory (FRAM). The semiconductor device CH may perform operations such as writing, reading, and erasing data DATA in response to signals received from the controller 10.

Each of the semiconductor devices CH may include a first structure ST1 and a second structure ST2 vertically overlapping the first structure ST1. In each of the semiconductor devices CH, the first structure ST1 may include a plurality of memory mats MAT1 and MAT2 spaced apart from each other.

Hereinafter, one semiconductor device CH will be mainly described.

Each of the plurality of memory mats MAT1 and MAT2 may include a plurality of memory blocks. For example, the first memory mat MAT1, among the plurality of memory mats MAT1 and MAT2, may include a plurality of first memory blocks BLK1, and the second memory mat MAT2, among the plurality of memory mats MAT1 and MAT2, may include a plurality of second memory blocks BLK2.

Each of the plurality of memory mats MAT1 and MAT2 may include a memory cell array MCA including three-dimensionally arranged memory cells. For example, in the first structure ST1, the first and second memory blocks BLK1 and BLK2 may include memory cells that may be arranged three-dimensionally and may include store data.

The second structure ST2 may include a peripheral circuit PC. The peripheral circuit PC may include an address decoder 93, a control logic 94, a page buffer 95, an input/output circuit 96, and a voltage generation circuit 97. Accordingly, in the semiconductor device CH, the first structure ST1 may include the plurality of memory mats MAT1 and MAT2 including the memory cell array MCA, and the second structure ST2 may include the peripheral circuit PC.

The first structure ST1 may further include word lines WL, string select lines SSL, ground select lines GSL, bit lines BL, erase control lines ECL, and a common source CSL.

The memory cell array MCA of each of the plurality of memory mats MAT1 and MAT2 may be electrically connected to the address decoder 93 of the peripheral circuit PC through the word lines WL, the string selection lines SSL, the ground selection lines GSL and the common source CSL, and may be electrically connected to the page buffer 95 of the peripheral circuit PC through the bit lines BL.

The address decoder 93 may select any one of the first and second memory blocks BLK1 and BLK2. The address decoder 93 may select any one of the word lines WL of the selected memory block. The address decoder 93 may transmit voltages provided from the voltage generation circuit 97 to the word line WL of the selected memory block or select lines SSL and GSL. The address decoder 93 may transmits a positive (+) high voltage program voltage to the selected word line during a program operation, and may transmit a positive (+) high voltage erase voltage to a bulk of the selected memory block during an erase operation.

The control logic 94 may receive the command CMD and the control signal CTRL from the controller 10, and may control the address decoder 93, the page buffer 95, and the input/output circuit 96 in response to the received signals. The control logic 94 may control the voltage generation circuit 97 generating various voltages required for an operation of the semiconductor device CH. For example, the control logic 94 may control a voltage level provided to the word lines WL and the bit lines BL when performing memory operations such as a program operation or an erase operation.

The voltage generation circuit 97 may generate various levels of voltages, such as a plurality of select read voltages, a plurality of non-select read voltages, a plurality of program pulses, a plurality of pass voltages, and a plurality of erase pulses, under the control of the control logic 94, and may provide the voltages to the address decoder 93 and the first and second memory blocks BLK1 and BLK2. For example, the voltage generation circuit 97 may generate a positive (+) high voltage corresponding to the plurality of program pulses or the plurality of erase pulses. In order to generate various levels of voltages as described above, the voltage generation circuit 97 may include a charge pump including at least one pumping capacitor.

The page buffer 95 can operate as a write driver or a sense amplifier depending on the operation mode. During a read operation, the page buffer 95 may sense a bit line BL of a selected memory cell among the three-dimensionally arranged memory cells in the first and second memory blocks BLK1 and BLK2 under the control of the control logic 94. The sensed data may be stored in latches provided in the page buffer 95. The page buffer 95 may dump the data stored in the latches to the input/output circuit 96 under the control of the control logic 94.

The input/output circuit 96 may temporarily store a command CMD, an address ADDR, a control signal CTRL, and data DATA provided from the outside of the semiconductor devices CH through the pad patterns PAD. The input/output circuit 96 may temporarily store the read data of the semiconductor device CH and output the read data to the outside through the pad patterns PAD at a specified time point.

Referring to FIG. 4, together with FIG. 1, FIG. 2, and FIG. 3 described above, an example of the data storage system 1 described above will be described. FIG. 4 is a schematic diagram illustrating a data storage system including a semiconductor device according to example embodiments of the present disclosure.

Referring to FIG. 4, together with FIG. 1, FIG. 2 and FIG. 3, the data storage system 1 may be a storage device including the semiconductor device CH or an electronic device including the storage device. For example, the data storage system 1 may be a solid-state drive device (SSD), a Universal Serial Bus (USB), a computing system, a medical device, or a communication device, including one or more semiconductor devices CH.

The second structure ST2 may be a peripheral circuit structure or peripheral circuit region including a decoder circuit 1110, a page buffer 95, and a logic circuit 1130.

The first structure ST1 may include a bit line BL, a common source CSL, word lines WL, first and second upper gate lines UL1 and UL2, first and second lower gate lines LL1 and LL2, and memory cell strings CSTR between the bit line BL and the common source CSL.

In the first structure ST1 illustrated in FIG. 4, each of the plurality of memory mats MAT1 and MAT2 may include the bit line BL, the common source CSL, the word lines WL, the first and second upper gate lines UL1 and UL2, the first and second lower gate lines LL1 and LL2, and the memory cell strings CSTR. The first lower gate line LL1 may be disposed on a level higher than that of the common source CSL. The second lower gate line LL2 may be disposed on a level higher than that of the first lower gate line LL1. The word lines WL may be disposed on a level higher than the second lower gate line LL2. The first gate upper line UL1 may be disposed on a level higher than the word lines WL. The second gate upper line UL2 may be disposed on a level higher than that of the first gate upper line UL1.

In the first structure ST1, each of the memory cell strings CSTR may include lower transistors LT1 and LT2 adjacent to the common source CSL, upper transistors UT1 and UT2 adjacent to the bit line BL, and a plurality of memory cell transistors MCT disposed between the lower transistors LT1 and LT2 and the upper transistors UT1 and UT2.

The number of the lower transistors LT1 and LT2 and the number of the upper transistors UT1 and UT2 may vary according to example embodiments. The plurality of memory cell transistors MCT may include information storage regions capable of storing information (data).

In example embodiments, the upper transistors UT1 and UT2 may include string select transistors, and the lower transistors LT1 and LT2 may include ground select transistors. The lower gate lines LL1 and LL2 may be gate electrodes of the lower transistors LT1 and LT2, respectively. The word lines WL may be gate electrodes of the memory cell transistors MCT, and the upper gate lines UL1 and UL2 may be gate electrodes of the upper transistors UT1 and UT2, respectively.

In example embodiments, the lower transistors LT1 and LT2 may include a first lower transistor LT1 and a second lower transistor LT2 on the first lower transistor LT1. The first and second lower transistors LT1 and LT2 may be connected in series. The first lower transistor LT1 may be a lower erase control transistor, and the second lower transistor LT2 may be a lower select transistor, for example, a ground select transistor. The first lower gate line LL1 may be a lower erase control gate electrode of the lower erase control transistor LT1, and the second lower gate line LL2 may be a lower select gate electrode of the lower select transistor LT2.

The first and second lower gate lines LL1 and LL2, the word lines WL, and the first and second upper gate lines UL1 and UL2 may be gate electrodes.

In example embodiments, the upper transistors UT1 and UT2 may include a first upper transistor UT1 and a second upper transistor UT2 on the first upper transistor UT1. The first and second upper transistors UT1 and UT2 may be connected to each other in series.

In one example, the first upper transistor UT1 may be an upper erase control transistor, and the second upper transistor UT2 may be an upper select transistor, for example, a string select transistor. In this case, the first upper gate line UL1 may be an upper erase control gate electrode of the upper erase control transistor UT1, and the second upper gate line UL2 may be a string select gate electrode of the string select transistor UT2.

At least one of the lower erase control transistor LT1 and the upper erase control transistor UT1 may be used for an erase operation of erasing data stored in the memory cell transistors MCT by utilizing a gate induced drain leakage (GIDL) phenomenon.

In some embodiments, the first upper transistor UT1 may be an upper select transistor, for example, a string select transistor, and the second upper transistor UT2 may be an upper erase control transistor. In this case, the first upper gate line UL1 may be a string selection gate electrode of the string selection transistor UT1, and the second upper gate line UL2 may be an upper erase control gate electrode of the upper erase control transistor UT2.

In example embodiments, the common source CSL, the first and second lower gate lines LL1 and LL2, the word lines WL, and the first and second upper gate lines UL1 and UL2 may be electrically connected to a decoder circuit 1110 through routing interconnection structures 1115 extending from an interior of the first structure ST1 to the second structure ST2.

In example embodiments, the routing interconnection structures 1115 may be connected to pad regions of the first and second lower gate lines LL1 and LL2, pad regions of the word lines WL, and pad regions of the first and second upper gate lines UL1 and UL2.

The bit lines BL may be electrically connected to the page buffer 95 through a routing interconnection structure 1125 extending from an interior of the second structure ST2 to the first structure ST1.

In the second structure ST2, the decoder circuit 1110 and the page buffer 95 may execute a control operation for at least one selected memory cell transistor, among the plurality of memory cell transistors MCT. The decoder circuit 1110 and the page buffer 95 may be controlled by the logic circuit 1130.

The semiconductor device CH may communicate with the controller 10 through the pad patterns PAD electrically connected to the logic circuit 1130. The pad patterns PAD may be electrically connected to the logic circuit 1130 through a routing interconnection structure 1135 extending from the interior of the first structure ST1 to the second structure ST2.

The controller 10 may include a processor 1210, a NAND controller 1220, and a host interface 1230.

The processor 1210 may control an overall operation of the data storage system 1 including the controller 10. The processor 1210 may operate according to a predetermined firmware, and may control the NAND controller 1220 to access the semiconductor device CH. The NAND controller 1220 may include a NAND interface 1221 configured to process communication with the semiconductor device CH. Through the NAND interface 1221, the control command for controlling the semiconductor device CH, the data to be written to the memory cell transistors MCT of the semiconductor device CH, the data to be read from the memory cell transistors MCT of the semiconductor device CH, and the like, may be transmitted. The host interface 1230 may provide a communication function between the data storage system 1 and the external host HOST (see FIG. 2). When the control command is received from the external host HOST (see FIG. 2) through the host interface 1230, the processor 1210 may control the semiconductor device CH in response to the control command.

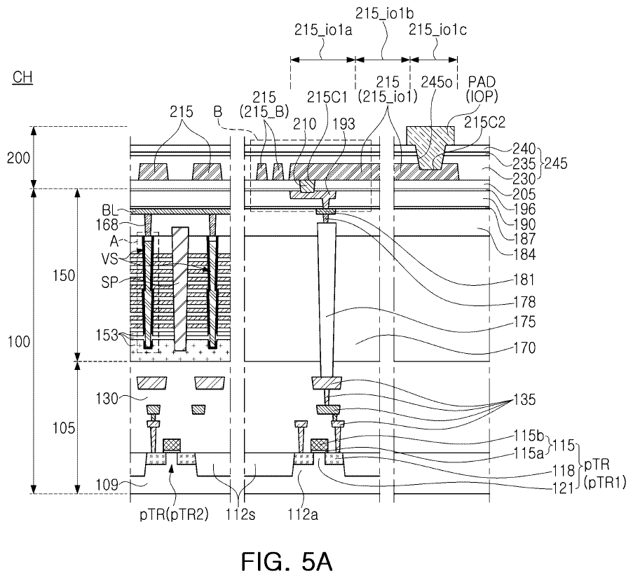

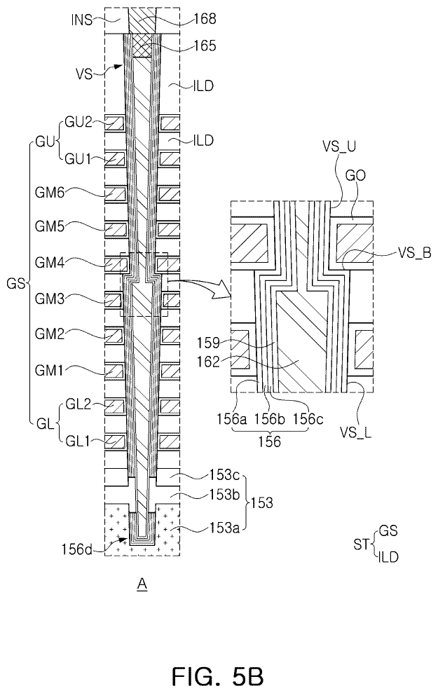

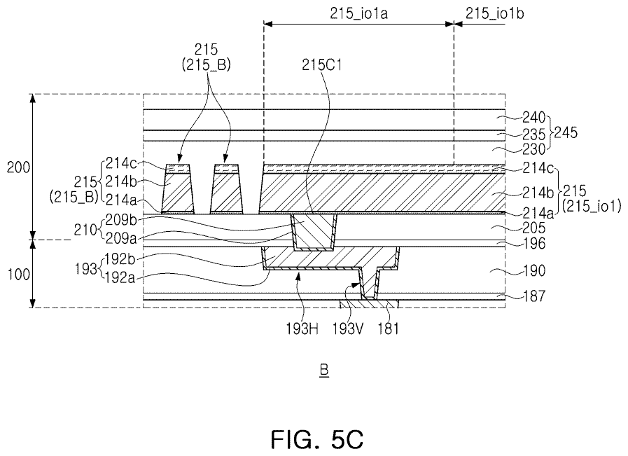

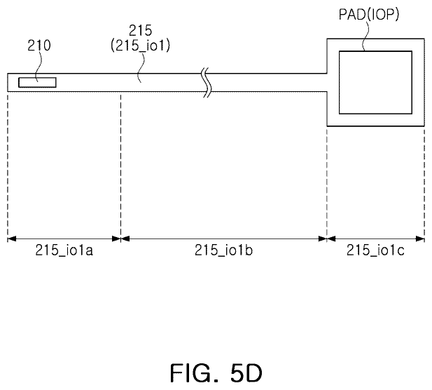

Next, with reference to FIGS. 5A, 5B, 5C and 5D, an example of the semiconductor device CH described with reference to FIGS. 1 to 4 above will be described. FIG. 5A is a cross-sectional view illustrating an example of the semiconductor device CH, FIG. 5B is a partially enlarged view illustrating a region indicated by ‘A’ in FIG. 5A, FIG. 5C is a partially enlarged view illustrating a region indicated by ‘B’ in FIG. 5A, and FIG. 5D is a conceptual plan view illustrating a first input/output interconnection line 215_io1, a conductive via 210, and a first input/output pad pattern IOP in a semiconductor device CH according to example embodiments of the present disclosure.

Referring to FIGS. 5A to 5D together with FIGS. 1 to 4, the semiconductor device CH may include a lower structure 100 and an upper structure 200 on the lower structure 100.

The lower structure 100 may include a peripheral region 105 and a memory region 150 vertically overlapping the peripheral region 105.

The peripheral region 105 may include a substrate 109, peripheral active regions 112a on the substrate 109, and a peripheral element separation region 112s defining the peripheral active regions 112a on the substrate 109. The substrate 109 may be a semiconductor substrate.

The peripheral region 105 may further include a peripheral circuit PTR, a peripheral interconnection structure 135, and an insulating structure 130 on the substrate 109.

The peripheral circuit PTR may include peripheral transistors pTR1 and pTR2. Each of the peripheral transistors pTR1 and pTR2 may include peripheral source/drain regions 118 spaced apart from each other in the peripheral active region 112a, peripheral channel regions 121 between the peripheral source/drain regions 118, and peripheral gates 115 on the peripheral active region 112a. The peripheral gates 115 may include peripheral gate dielectric layers 115a, and peripheral gate electrodes 115b on the peripheral gate dielectric layers 115a. The peripheral interconnection structure 135 may be embedded in the insulating structure 130, and may be electrically connected to the peripheral transistors pTR1 and pTR2.

The memory region 150 may include a source structure 153, and a gate stack structure GS disposed on the source structure 153.

The gate stack structure GS may include a plurality of gate electrodes GL, GM and GU spaced apart from each other in a vertical direction.

The plurality of gate electrodes GL, GM and GU may include one or a plurality of lower gate electrodes GL, a plurality of intermediate gate electrodes GM disposed on the one or a plurality of lower gate electrodes GL, and one or a plurality of upper gate electrodes GU disposed on the plurality of intermediate gate electrodes GM.

The one or a plurality of lower gate electrodes GL may include a first lower gate electrode GL1 and a second lower gate electrode GL2 on the first lower gate electrode GL1. The first and second lower gate electrodes GL1 and GL2 may be the first and second lower gate lines LL1 and LL2 (see FIG. 4) described above.

The plurality of intermediate gate electrodes GM may include the word lines WL (see FIG. 4) described above. Accordingly, the plurality of intermediate gate electrodes GM may also be referred to as word lines.

The plurality of intermediate gate electrodes GM may include a first intermediate gate electrode GM1, a second intermediate gate electrode GM2 on the first intermediate gate electrode GM1, a third intermediate gate electrode GM3 on the second intermediate gate electrode GM2, a fourth intermediate gate electrode GM4 on the third intermediate gate electrode GM3, a fifth intermediate gate electrode GM5 on the fourth intermediate gate electrode GM4, and a sixth intermediate gate electrode GM6 on the fifth intermediate gate electrode GM5.

The one or plurality of upper gate electrodes GU may include a first upper gate electrode GU1 and a second upper gate electrode GU2 on the first upper gate electrode GU1. The first and second upper gate electrodes GU1 and GU2 may be the first and second upper gate lines UL1 and UL2 (see FIG. 4) described above.

In example embodiments, the number of the plurality of gate electrodes GL, GM and GU illustrated in the drawings is an example, and the number of the plurality of gate electrodes GL, GM and GU may be different from the number illustrated in the drawings.

The memory region 150 may further include interlayer insulating layers ILD alternately and repeatedly stacked with the plurality of gate electrodes GL, GM and GU. Among the plurality of gate electrodes GL, GM and GU and the interlayer insulating layers ILD, an uppermost layer and a lowermost layer may be disposed as the interlayer insulating layers.

The memory region 150 may further include a separation pattern SP penetrating through or extending into the plurality of gate electrodes GL, GM and GU and the interlayer insulating layers ILD. The separation pattern SP may penetrate through or extend into the plurality of gate electrodes GL, GM and GU and may divide the plurality of gate electrodes GL, GM and GU. The memory region 150 may further include a dielectric layer GO covering or overlapping upper surfaces, side surfaces, and lower surfaces of each of the plurality of gate electrodes GL, GM and GU.

The memory region 150 may further include vertical memory structures VS. The vertical memory structures VS may penetrate through or extend into the gate electrode structures GS and the interlayer insulating layers ILD in a vertical direction.

Each of the vertical memory structures VS may include an insulating core region 162, a channel layer 159 on an external surface of the insulating core region 162, an information storage structure 156 on an external surface of the channel layer 159, and a pad layer 165 disposed on the insulating core region 162 and in contact with the channel layer 159.

The channel layer 159 may include a semiconductor material such as silicon. The pad layer 165 may include at least one of doped polysilicon, a metal nitride (e.g., TiN, or the like), a metal (e.g., W, or the like.), and/or a metal-semiconductor compound (e.g., TiSi, or the like). The information storage structure 156 may include a first dielectric layer 156a, a second dielectric layer 156c, and an information storage layer 156b between the first dielectric layer 156c and the second dielectric layer 156a. The first dielectric layer 156a may include at least one of silicon oxide and/or a high-K dielectric. The second dielectric layer 156c may include silicon oxide or silicon oxide doped with an impurity. The second dielectric layer 156c may be in contact with the channel layer 159.

The information storage layer 156b may include a material capable of trapping charges and storing information, for example, silicon nitride. The information storage layer 156b may include regions capable of storing information in a semiconductor device such as a flash memory device.

In example embodiments, the information storage structure 156 may include the information storage layer 156b capable of storing information by trapping charges, but the example embodiment is not limited thereto. For example, the information storage structure 156 may be an information storage structure used in a ferroelectric memory that may store information by utilizing remnant polarization by a dipole.

Each of the vertical memory structures VS may include a lower vertical portion VS_L, an upper vertical portion VS_U on the lower vertical portion VS_L, and a bonding portion VS_B between the lower vertical portion VS_L and the upper vertical portion VS_U.

In the vertical memory structures VS, the bonding portions VS_B may be arranged between the plurality of intermediate gates GM. For example, the bonding portions VS_B may be disposed between the third intermediate gate electrode GM3 and the fourth intermediate gate electrode GM4 among the plurality of intermediate gates GM.

In each of the vertical memory structures VS, the bonding portion VS_B may have a side surface bent from a side surface of the lower vertical portion VS_L and a side surface of the upper vertical portion VS_U.

The vertical memory structures VS may be in contact with the source structure 153.

The source structure 153 may include a first conductive layer 153a, a second conductive layer 153b on the first conductive layer 153a, and a third conductive layer 153c on the second conductive layer 153b.

In the vertical memory structures VS described above, the information storage structure 156 may extend to cover or overlap a lower surface of the insulating core region 162, and the second conductive layer 153b may penetrate through or extend into the information storage structure 156 and may be in contact with the channel layer 159. The information storage structure 156 may include a dummy portion 156d separated by the second conductive layer 153b and in contact with the first conductive layer 153a.

At least one of the first conductive layer 153a, the second conductive layer 153b, and the third conductive layer 153c may include a silicon layer having an N-type conductivity type. For example, the first conductive layer 153a, the second conductive layer 153b, and the third conductive layer 153c may include polysilicon having an N-type conductivity type.

The memory region 150 may further include an insulating structure 170 disposed outside the gate stack structure GS, and a first insulating layer 184 on the gate stack structure GS and the insulating structure 170.

The memory region 150 may further include the bit line BL described above. The bit line BL may be disposed on the gate stack structure GS.

The memory region 150 may further include bit line contact plugs 168 disposed between the bit line BL and the vertical memory structures VS and electrically connecting the bit line BL and the vertical memory structures VS.

The memory region 150 may further include lower interconnection lines 181 disposed on substantially the same level as the bit line BL, and a contact structures 175 and 178 electrically connecting the lower interconnection lines 181 and the peripheral interconnection structure 135. The contact structures 175 and 178 may include at least two contact plugs disposed on different levels. For example, the contact structures 175 and 178 may include a first contact plug 175 and a second contact plug 178 on the first contact plug (175).

The memory region 150 may further include the bit line BL, the lower interconnection lines 181, and a first etch stop layer 187 on the first insulating layer 184, an inter-metal insulating layer 190 on the first etch stop layer 187, an intermediate interconnection structure 193 embedded in the inter-metal insulating layer 190, and a second etch stop layer 196 on the inter-metal insulating layer 190 and the intermediate interconnection structure 193.

The intermediate interconnection structure 193 may include an interconnection line portion 193H and a via portion 193V extending downwardly from the interconnection line portion 193H and penetrating through or extending into the first etch stop layer 187 and electrically connected to the lower interconnection line 181. The intermediate interconnection structure 193 may include a conductive barrier layer 192a and a conductive pattern 192b on the conductive barrier layer 192a.

The upper structure 200 may include an inter-metal insulating layer 205 disposed on the lower structure 100, upper conductive vias 210 penetrating through or extending into the inter-metal insulating layer 205, upper conductive patterns 215 disposed on the inter-metal insulating layer 205, and a capping insulating structure 245 disposed on the inter-metal insulating layer 205 and the upper conductive patterns 215.

Each of the upper conductive patterns 215 may include an adhesion layer 214a, an intermediate conductive layer 214b, and a capping conductive layer 214c, which are sequentially stacked.

The adhesion layer 214a may include Ti, but the example embodiment is not limited thereto. For example, the adhesion layer 214a may include Ta, TiN, TaN, or the like. The intermediate conductive layer 214b may have a thickness greater than a thickness of the adhesion layer 214a. The intermediate conductive layer 214b may include Al, but the example embodiment is not limited thereto. For example, the intermediate conductive layer 214b may include W or Mo. The upper conductive layer 214c may have a thickness greater than the thickness of the adhesion layer 214a, and may have a thickness less than the thickness of the intermediate conductive layer 214b. The upper conductive layer 214c may include TiN, but the example embodiment is not limited thereto. For example, the upper conductive layer 214c may include TaN or WN.

Each of the upper conductive patterns 215 may have an inclined side surface so that a width of a lower region thereof is greater than a width of an upper region thereof. For example, each of the upper conductive patterns 215 may have a positive inclined side surface.

The capping insulating structure 245 may include an upper insulating layer 230, a capping insulating layer 235 on the upper insulating layer 230, and a passivation layer 240 on the barrier capping layer 235.

The upper insulating layer 230 may include an insulating material that may supply hydrogen (H). For example, the upper insulating layer 230 may include silicon oxide containing hydrogen. The upper insulating layer 230 may be formed of HDP silicon oxide containing hydrogen or TEOS silicon oxide containing hydrogen. For example, in a hydrogen heat treatment process, hydrogen (H) in the upper insulating layer 230 may diffuse into the memory region 150 and the peripheral region 105 to remove defects existing on a surface of a semiconductor material layer formed of a semiconductor material, or may improve interface characteristics between the semiconductor material layer and the insulating layer. In the memory region 150, the channel layer 159 may be formed of the semiconductor material layer, and in the peripheral region 105, the peripheral active regions 112a may be formed of the semiconductor material layer. Accordingly, the upper insulating layer 230 may be a hydrogen supply source that may supply hydrogen in the hydrogen heat treatment process for improving the performance and reliability of the semiconductor device CH. In this manner, the upper insulating layer 230, which may be a hydrogen supply source, may cover or overlap upper surfaces and side surfaces of each of the upper conductive patterns 215.

The barrier capping layer 235 may include a material different from a material of the upper insulating layer 230 and a material of the passivation layer 240. The barrier capping layer 295 may include a silicon nitride or a silicon nitride-based material. The passivation layer 240 may include a polyimide or a polyimide-based material.

The capping insulating structure 245 may include pad openings 2450 penetrating through or extending into the capping insulating structure 245.

The upper structure 200 may further include the pad patterns PAD (see FIG. 1) as described above.

In example embodiments, the pad patterns PAD may penetrate through or extend into the capping insulating structure 245. The pad patterns PAD may include the input/output pad IOP (see FIG. 1) and the power pads PowP (see FIG. 1) as described above. The pad patterns PAD may include a portion disposed in the pad openings 2450 penetrating through or extending into the capping insulating structure 245.

In example embodiments, without forming the pad patterns PAD as in FIG. 5a in a separate process, regions of the upper conductive patterns 215 exposed by the pad openings 2450, among the upper conductive patterns 215, may be defined as the pad patterns PAD described in FIG. 1.

Hereinafter, for easier understanding, the structure of the pad patterns PAD as in FIG. 5A will be described, but the example embodiment of the present disclosure is not limited thereto. For example, according to example embodiments, regions of the upper conductive patterns 215 exposed by the pad openings 2450 may be the pad patterns PAD described in FIG. 1.

The upper conductive vias 210 may penetrate through or extend into the inter-metal insulating layer 205 and extend downwardly to penetrate through or extend into the second etch stop layer 196, and may be electrically connected to the intermediate interconnection structures 193.

The upper conductive patterns 215 may include upper interconnection lines not electrically isolated, and a barrier structure 215_B electrically isolated. Among the upper conductive patterns 215, the upper interconnection lines may include input/output interconnection lines electrically connected to the input/output pad IOP, among the pad patterns PAD, and power interconnection lines electrically connected to the power pads PowP, among the pad patterns PAD.

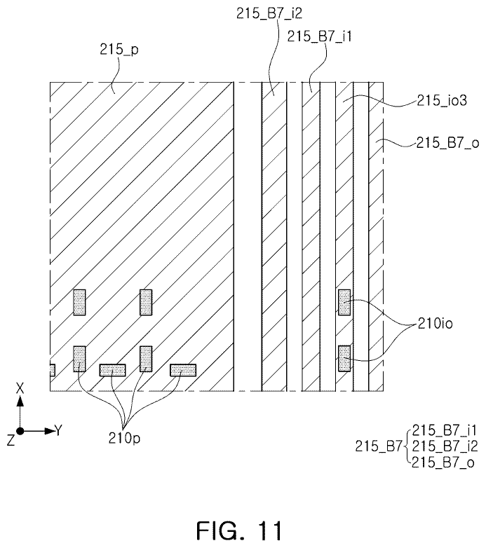

First, in FIGS. 5A to 5D, a first input/output interconnection line 215_io1, among the input/output interconnection lines, will be mainly described, and the power interconnection lines will be described in FIGS. 11, 12, 13A to 13E, 14A, and 14B described below.

The first input/output interconnection line 215_io1 may include a connection region 215_io1a, a pad region 215_io1c, and an interconnection line region 215_io1b between the first and pad regions 215_io1a and 215_io1c.

The connection region 215_io1a may be a region connected to the upper conductive via 210, and the pad region 215_io1c may be a region connected to the input/output pad IOP. According to example embodiments, at least a portion of the pad region 215_io1c exposed by the pad opening 2450 may be an input/output pad IOP. Accordingly, the pad region 215_io1c may also be referred to as an input/output pad.

The barrier structure 215_B may be adjacent to the connection region 215_io1a. In order to prevent or inhibit an interfacial surface 215C1 between the connection region 215_io1a and the conductive via 210 from being oxidized, the barrier structure 215_B may be disposed to be adjacent to the connection region 215_io1a and at least partially surround three surfaces of the connection region 215_io1a in plan view.

Next, referring to FIGS. 6A and 6B, examples of the connection region 215_io1a and the pad region 215_io1c of the first input/output interconnection line 215_io1, the conductive via 210, and the barrier structure 215_B described above will be described. FIG. 6A is a plan view illustrating a planar shape of the connection region 215_io1a and the pad region 215_io1c of the first input/output interconnection line 215_io1, a planar shape of the conductive via 210, and a planar shape of the barrier structure 215_B, and FIG. 6B, a partially enlarged cross-sectional view illustrating a region taken along line I-I′ of FIG. 6A on the same level as the partially enlarged cross-sectional view of FIG. 5C.

Referring to FIGS. 6A and 6B along with FIGS. 1 to 5C, in the first input/output interconnection line 215_io1, the connection region 215_io1a may be a line shape extending in a first direction (X-direction), and the interconnection line region 215_io1b may extend from the connection region 215_io1a in the first direction (X-direction).

The upper conductive via 210 may be a bar shape extending in the first direction (X-direction).

In plan view, the connection region 215_io1a may have a first side surface S1 and a second side surface S2 opposing each other in a second direction (Y-direction), perpendicular to the first direction (X-direction), and a third side surface S3 extending from end portions of the first and second side surfaces S1 and S2.

The upper conductive via 210 may have a first length in the first direction (X-direction), and in the first connection region 215_io1a, a distance between a portion in contact with the upper conductive via 210 and the interconnection line region 215_io1b may be at least twice as large as the first length in the first direction (X-direction).

The barrier structure 215_B may include an internal barrier structure 215_B_i adjacent to the connection region 215_io1a and an external barrier structure 215_B_o adjacent to the internal barrier structure 215_B_i and including at least two external line portions in parallel with each other.

The internal barrier structure may include a first internal line portion 215_B_i1 facing the first side surface S1 of the connection region 215_io1a, a second internal line portion 215_B_i2 facing the second side surface S2 of the connection region 215_io1a, and a third internal portion 215_B_i3 extending from the first and second internal line portions 215_B_i1 and 215_B_i2 and facing the third side surface S3 of the connection region 215_io1a.

The external barrier structure 215_B_o may include a first external line portion 215_B_o1 adjacent to the first internal line portion 215_B_i1 and in parallel with the first internal line portion 215_B_i1, a second external line portion 215_B_o2 adjacent to the second internal line portion 215_B_i2 and in parallel with the second internal line portion 215_B_i2, and a third external portion 215_B_o3 facing the third internal portion 215_B_i3. The third external portion 215_B_o3 may extend from the first and second external line portions 215_B_o1 and 215_B_o2.

As described above, the upper insulating layer 230 may be a hydrogen supply source capable of supplying hydrogen in a hydrogen heat treatment process for improving the performance and reliability of the semiconductor device CH, and the upper insulating layer 230 may cover or overlap upper surfaces and side surfaces of each of the upper conductive patterns 215.

As described above, each of the upper conductive patterns 215 may include the adhesion layer 214a, the intermediate conductive layer 214b, and the capping conductive layer 214c.

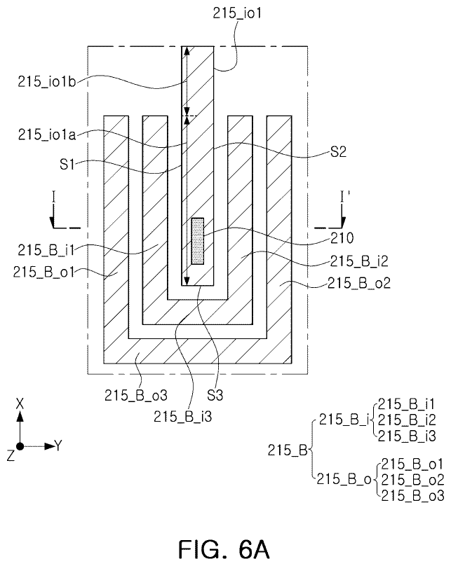

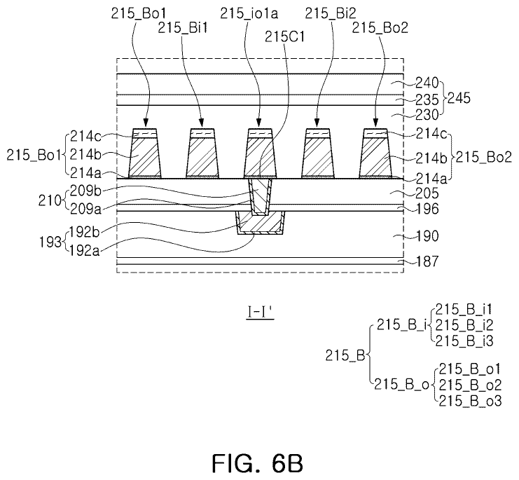

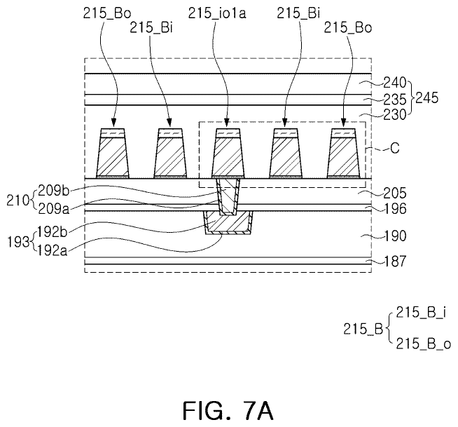

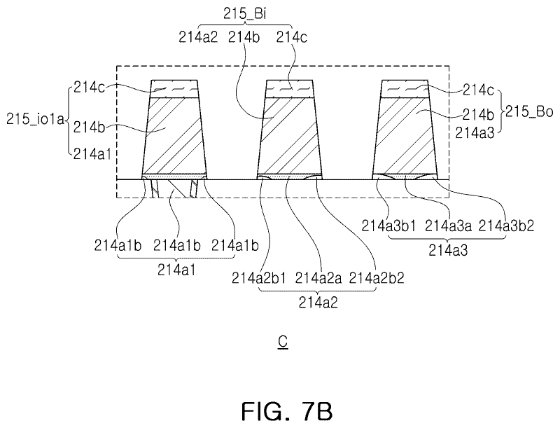

While hydrogen is diffused in the upper insulating layer 230 in the hydrogen heat treatment process, oxygen in the upper insulating layer 230 may react with the adhesion layer 214a of each of the upper conductive patterns 215 to form a metal oxide. For example, in at least one upper conductive pattern of the upper conductive patterns 215, at least a portion of the adhesion layer 214a may be replaced with an adhesion layer including a metal oxide. In this manner, an example of an upper conductive pattern 215 including an adhesion layer in which at least the portion thereof includes the metal oxide will be described with reference to FIGS. 7A and 7B. FIG. 7A is a cross-sectional view illustrating that at least a portion of the adhesion layer 214a is oxidized to form a metal oxide, in a cross-sectional structure corresponding to FIG. 6B, and FIG. 7B is an enlarged partial view of a region indicated by ‘C’ in FIG. 7A.

Referring to FIGS. 7A and 7B, in the external barrier structure 215_B_o, the adhesion layer 214c (see FIG. 6B) may be replaced with an adhesion layer 214a3 in which at least a portion thereof includes a metal oxide. For example, in the external barrier structure 215_B_o, the adhesion layer 214a3 may include a metal material portion 214a3a and metal oxide portions 214a3b1 and 214a3b disposed on both sides of the metal material portion 214a3a. The metal material portion 214a3a may include a Ti material, and the metal oxide portions 214a3b1 and 214a3b2 may include TiO.

In the internal barrier structure 215_B_i, the adhesion layer 214c (see FIG. 6b) may be replaced with an adhesion layer 214a2 in which at least a portion thereof includes a metal oxide. For example, in the internal barrier structure 215_B_i, the adhesion layer 214a2 may include a metal material portion 214a2a and metal oxide portions 214a2b1 and 214a2b2 disposed on both sides of the metal material portion 214a2a.

In the connection region 215_io1a, the adhesion layer 214c (see FIG. 6b) may be replaced with an adhesion layer 214a1 in which at least a portion thereof includes a metal oxide. For example, in the connection region 215_io1a, the adhesion layer 214a1 may include a metal material portion 214a1a and metal oxide portions 214a1b disposed on both sides of the metal material portion 214a1a.

In the connection region 215_io1a, the metal material portion 214a1a may be in contact with the conductive via 210, and the metal oxide portions 214a1b may be spaced apart from the conductive via 210.

In the cross-sectional structure as in FIGS. 7A and 7B, at least one of the metal oxide portions 214a2b1 and 214a2b2 of the internal barrier structure 215_B_i may have a maximum thickness and/or maximum width smaller than a maximum thickness/width of at least one of the metal oxide portions 214a3b1 and 214a3b2 of the external barrier structure 215_B_o.

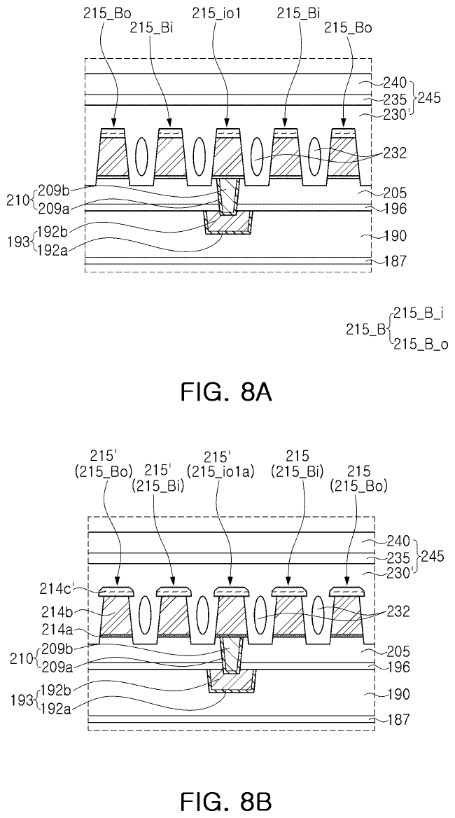

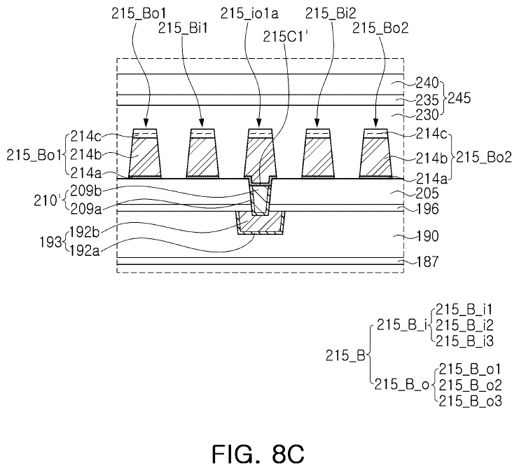

Next, with reference to FIG. 8A, a modified example of the upper insulating layer 230 will be described. FIG. 8A is a partially enlarged cross-sectional view corresponding to FIG. 6A.

Referring to FIG. 8A, the upper insulating layer 230 described above may be replaced with an upper insulating layer 230′ extending into the inter-metal insulating layer 205 so as to have lower surfaces disposed on a level lower than that of the lower surfaces of the upper conductive patterns 215.

The upper insulating layer 230′ may include an air gap 232 disposed between adjacent upper conductive patterns 215, among the upper conductive patterns 215.

Next, referring to FIG. 8B, a modified example of the upper conductive patterns 215 described above will be described. FIG. 8B is a partially enlarged cross-sectional view corresponding to FIG. 8A.

Referring to FIG. 8B, in the upper conductive patterns 215 described above, the capping conductive layer 214c may be replaced with a capping conductive layer 214c′ having a side surface that is not aligned with the side surface of the intermediate conductive layer 214b and the side surface of the adhesion layer 214a. A width of the capping conductive layer 214c′ may be larger than a width of the intermediate conductive layer 214b.

Next, referring to FIG. 8C, a modified example of the conductive via 210 described above will be described. FIG. 8C is a partially enlarged cross-sectional view corresponding to FIG. 6A.

Referring to FIG. 8C, an upper surface of the conductive via 210 may be disposed on a level lower than that of an upper surface of the inter-metal insulating layer 205. Accordingly, a surface 215C1′ on which the first input/output interconnection line 215_io1 and the conductive via 210 are in contact with each other may be lower than an upper surface of the inter-metal insulating layer 205 and a lower surface of the barrier structure 215_B. The upper surface of the conductive via 210 may be lower than the upper surface of the inter-metal insulating layer 205 and the lower surface of the barrier structure 215_B.

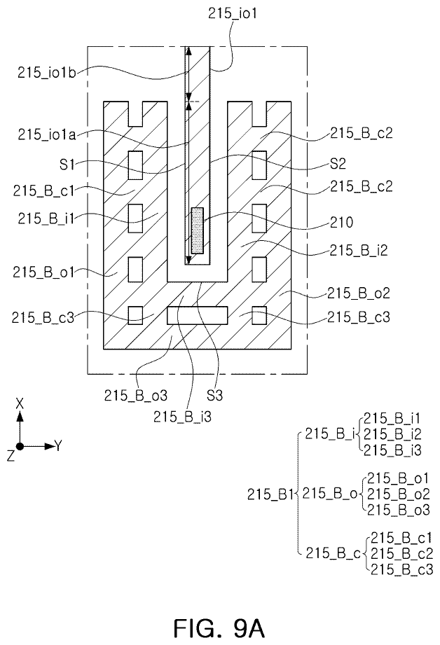

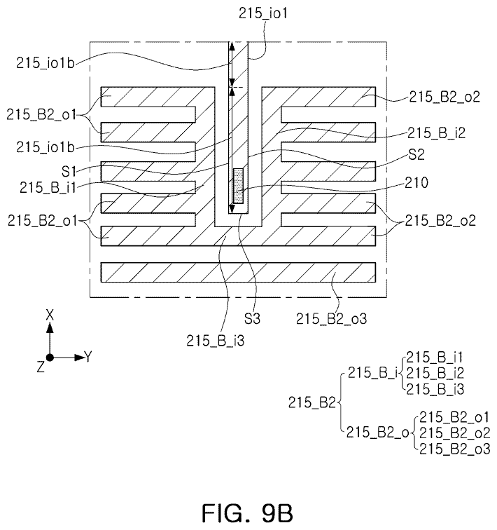

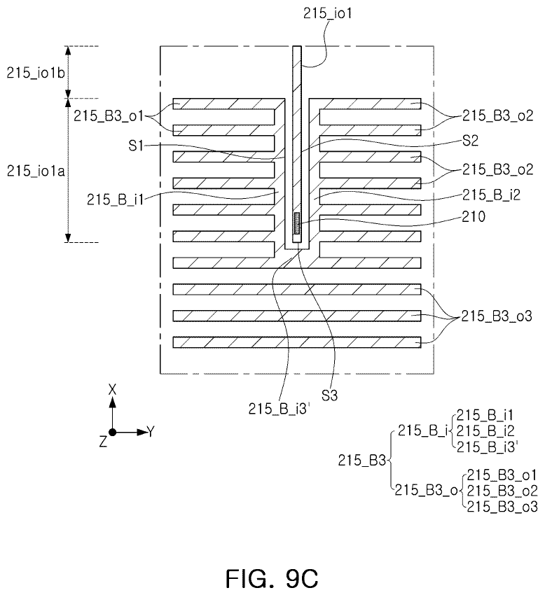

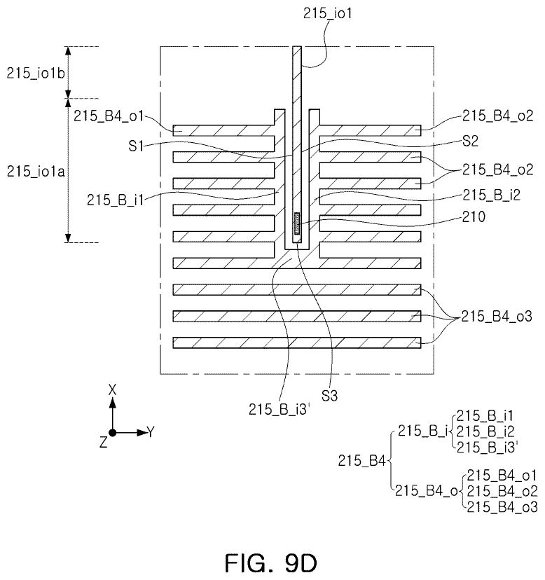

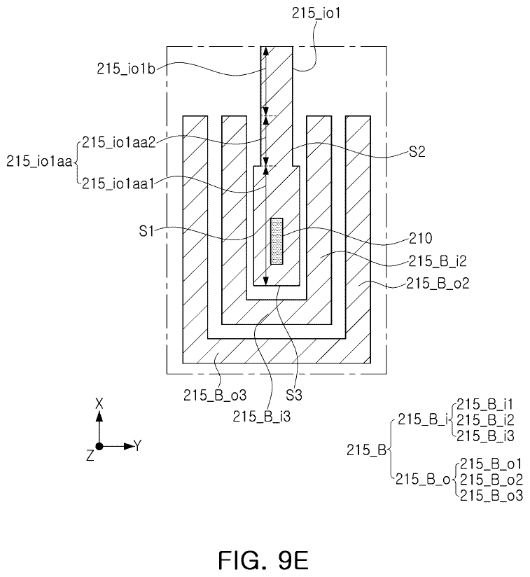

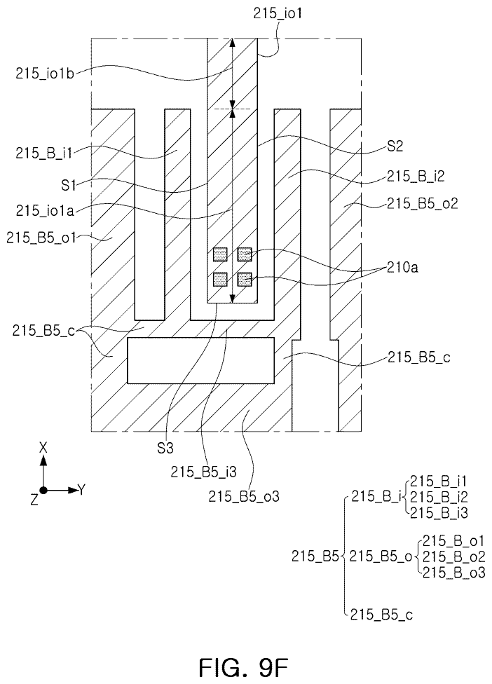

Next, referring to FIGS. 9A to 9D, respectively, various examples of the planar shape of the barrier structure 215_B described above will be described. FIGS. 9A to 9D are partially enlarged plan views for describing various examples of the planar shape of the barrier structure 215_B (see FIG. 6A) described above.

In one example, referring to FIG. 9A, the barrier structure 215_B (see FIG. 6A) described above may be replaced with a barrier structure 215B1 further including connecting portions 215_B_c. For example, the barrier structure 215B1 may include the internal barrier structure 215_B_i and the external barrier structure 215_B_o as described in FIG. 6A, and in the barrier structure 215B1, connecting portions 215B_c may include at least one first connecting portion 215_B_c1 connecting a first internal line portion 215b_i1 and a first external line portion 215b_o1, at least one second connecting portion 215_B_c2 connecting a second internal line portion 215b_i2 and the second internal line portion 215b_o1, and a third connecting portion 215_B_c3 connecting the third internal portion 215_B_i3 and the third external portion 215_B_o3.

In one example, referring to FIG. 9B, the barrier structure 215_B (see FIG. 6A) described above may be replaced with a barrier structure 215_B2 as in FIG. 9B. The barrier structure 215_B2 may include the internal barrier structure 215_B_i described in FIG. 6A, and may include an external barrier structure 215_B2_o that may replace the external barrier structure 215_B_o (see FIG. 6A) as in FIG. 6A.

The external barrier structure 215_B2_o may include first external line portions 215_B2_o1 extending from the first internal line portion 215_B_i1 in a direction away from the connection region 215_io1a and spaced apart from each other in the first direction (X-direction), second external line portions 215_B2_o2 extending from the second internal line portion 215_B_i2 in a direction away from the connection region 215_io1a and spaced apart from each other in the first direction (X-direction), and third external portions 215_B2_o3 facing the third internal portion 215_B_i3 and extending in the second direction (Y-direction). In one example, referring to FIG. 9C, the above-described barrier structure 215_B2 (see FIG. 9B) may be replaced with a barrier structure 215_B3 as in FIG. 9C. The barrier structure 215_B3 may include the internal barrier structure 215_B_i as described in FIG. 9B, and may include an external barrier structure 215_B3_o with which the external barrier structure 215_B2_o (see FIG. 9B) as in FIG. 9B may be replaced. For example, the first external line portions 215_B2_o1 (see FIG. 9B) described in FIG. 9B may be replaced with first external line portions 215_B3_o1 as in FIG. 9C, the second external line portions 215_B2_o2 (see FIG. 9B) described in FIG. 9B may be replaced with second external line portions 215_B3_o2 as in FIG. 9C, and the third external portion 215_B2_o3 (see FIG. 9B) described in FIG. 9B may be replaced with the third external portions 215_B3_o2 as in FIG. 9C.

Each of the third external portions 215_B3_o2 may be a line or bar shape extending in the second direction (Y-direction). The third external portions 215_B3_o2 may be in parallel with each other.

In the first external line portions 215_B3_o1, a separation distance between the first external line portions 215_B3_o1 may be greater than widths of each of the first external line portions 215_B3_o1. In the second external line portions 215_B3_o2, a separation distance between the second external line portions 215_B3_o2 may be greater than widths of each of the second external line portions 215_B3_o2.

In an example, in the internal barrier structure 215_B_i, the third internal portion 215_B_i3 in FIG. 9B may be replaced with a third internal portion 215_Bi3′ which a width thereof in the first direction (X-direction) is increased.

The width of the third internal portion 215_Bi3′ in the first direction (X-direction) may be greater than widths of each of the first and second internal line portions 215_B_i1 and 215_B_i2 in the second direction (Y-direction).

In one example, referring to FIG. 9D, the barrier structure 215_B3 (see FIG. 9C) described above may be replaced with a barrier structure 215_B4 as in FIG. 9D. The barrier structure 215_B4 may include the internal barrier structure 215_B_i as described in FIG. 9C, and may include an external barrier structure 215_B4_o with which the external barrier structure 215_B3_o (see FIG. 9C) as described in FIG. 9C may be replaced. For example, the first external line portions 215_B3_o1 (see FIG. 9C) described in FIG. 9C may be replaced with first external line portions 215_B4_o1 described in FIG. 9D, the second external line portions 215_B3_o2 (see FIG. 9C) described in FIG. 9C may be replaced with second external line portions 215_B4_o2 described in FIG. 9D, and the third external portion 215_B2_o3 (see FIG. 9B) described in FIG. 9C may be substantially identical to the third external portions 215_B4_o2 described in FIG. 9D.

In the first external line portions 215_B3_o1, the separation distance between the first external line portions 215_B3_o1 may be greater than the widths of each of the first external line portions 215_B3_o1. In the second external line portions 215_B3_o2, the separation distance between the second external line portions 215_B3_o2 may be greater than the width of each of the second external line portions 215_B3_o2.

In an example, in the internal barrier structure 215_B_i, the first and second internal line portions 215_B_i1 and 215_B_i2 may be shaped to protrude in a direction oriented toward the interconnection line region 215_io1b from the connection region 215_io1a rather than the first and second internal line portions 215_B_i1 and 215_B_i2.

Next, referring to FIG. 9E, an example of the planar shape of the connection region 215_io1a described above will be described. FIG. 9E is a partially enlarged planar view illustrating an example of the planar shape of the connection region 215_io1a described above.

In one example, referring to FIG. 9E, the connection region 215_io1a described above may be replaced with a connection region 215_io1aa including a first-first connection region 215_io1aa2 disposed adjacent to the interconnection line region 215_io1b and having the same width as that of the interconnection line region 215_io1b and a first-second connection region 215_io1aa1 extending from the first-first connection region 215_io1aa2 and having a width greater than the first-first connection region 215_io1aa2 and connected to the upper conductive via 210.

Next, referring to FIG. 9F, an example of the planar shape of the upper conductive via 210 described above and an example of the planar shape of the barrier structure 215_B described above will be described. FIG. 9F is a partially enlarged plan view illustrating an example of the upper conductive via 210 (see FIG. 6A) described above and an example of the planar shape of the barrier structure 215_B (see FIG. 6A) described above.

In one example, referring to FIG. 9F, the upper conductive via 210 (see FIG. 6A) described above may be replaced with a plurality of upper conductive vias 210a spaced apart from each other. For example, the upper conductive vias 210a may be arranged in the first direction (X-direction) and/or the second direction (Y-direction).

The barrier structure 215_B (see FIG. 6A) described above may be replaced with a barrier structure 215_B5 as in FIG. 9F. The barrier structure 215_B5 may include the internal barrier structure 215_B_i as described in FIG. 6A, and may include an external barrier structure 215_B5_o with which the external barrier structure 215_B_o (see FIG. 6A) as described in FIG. 6A may be replaced, and may include connecting portions 215_B5_c that may connect the internal barrier structure 215_B_i and the external barrier structure 215_B5_o.

The external barrier structure 215_B5_o may include a first external line portion 215_B5_o1 in parallel with the first internal line portion 215_B_i1, a second external line portion 215_B5_o2 in parallel with the second internal line portion 215_B_i2, and a third external portion 215_B5_o3 in parallel with the third internal portion 215_B5_i3.

The connecting portions 215_B5_c may connect the first internal line portion 215_B_i1 and the first external line portion 215_B5_o1, may connect the first external line portion 215_B5_o1 and the third internal portion 215_B5_i3, and may connect the third internal portion 215_B5_i3 and the third external portion 215_B5_o3.

Widths of each of the first and second external line portions 215_B_o1 and 215B_o2 may be larger than widths of each of the first and second internal line portions 215_B_i1 and 215B_i2.

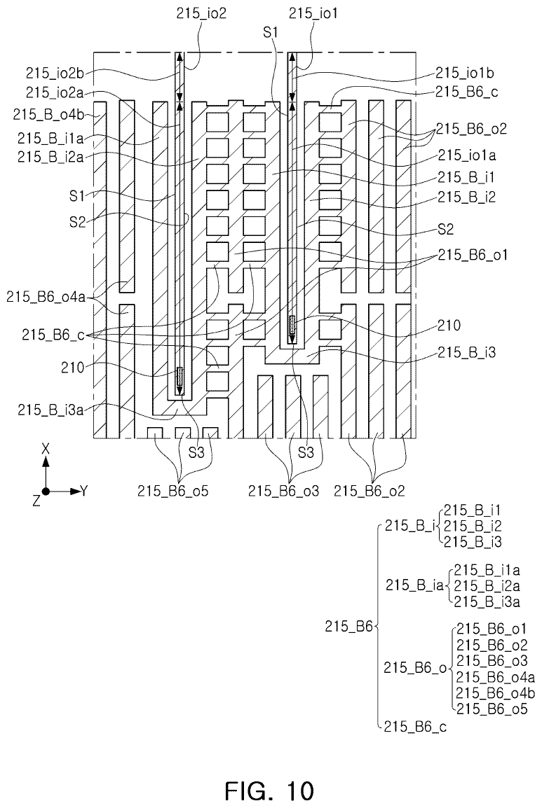

Next, with reference to FIG. 10, an example of a plurality of input/output interconnection lines and a barrier structure adjacent thereto will be described. FIG. 10 is a partially enlarged plan view illustrating a plurality of input/output interconnection lines and a barrier structure.

In one example, with reference to FIG. 10, the upper conductive patterns 215 described above may include a first input/output interconnection line 215_io1, a second input/output interconnection line 215_io2 in parallel with the first input/output interconnection line 215_io1, and a barrier structure 215_B6 adjacent to the first and second input/output interconnection lines 215_io1 and 215_io2.

The first input/output interconnection line 215_io1 may include a connection region 215_io1a having a line shape extending in the first direction (X-direction) and connected to the upper conductive via 210 and disposed adjacent to the barrier structure 215_B6, and an interconnection line region 215_io1b extending from the connection region 215_io1a.

The second input/output interconnection line 215_io2 may include a connection region 215_io2a having a line shape extending in the first direction (X-direction) and connected to the upper conductive via 210 and disposed adjacent to the barrier structure 215_B6, and an interconnection line region 215_io2b extending from the connection region 215_io2a.

A length of the connection region 215_io2a of the second input/output interconnection line 215_io2 may be greater than a length of the connection region 215_io1a of the first input/output interconnection line 215_io1.

Each of the connection regions 215_io1a and 215_io2a of the first and second input/output interconnection lines 215_io1 and 215_io2 may have the first and second side surfaces S1 and S2 opposing each other, as described in FIG. 6A, and a third side surface S3 extending from ends of the first and second side surfaces S1 and S2.

The barrier structure 215_B6 may include a first internal barrier structure 215_B_i adjacent to the connection region 215_io1a of the first input/output interconnection line 215_io1 and a second internal barrier structure 215_B_ia adjacent to the connection region 215_io2a of the second input/output interconnection line 215_io2.

The first internal barrier structure 215_B_i may include a first-first internal line portion 215_B_i1 facing the first side surface S1 of the connection region 215_io1a of the first input/output interconnection line 215_io1, a second-first internal line portion 215_B_i2 facing the second side surface S2 of the connection region 215_io1a, and a third-first internal portion 215_B_i3 extending from the first-first and second-first internal line portions 215_B_i1 and 215_B_i2 and facing the third side surface S3 of the connection region 215_io1a.

The second internal barrier structure 215_B_ia may include a first-second internal line portion 215_B_i1a facing the first side surface S1 of the connection region 215_io2a of the second input/output interconnection line 215_io2, a second-second internal line portion 215_B_i2a facing the second side surface S2 of the connection region 215_io2a, and a third-second internal portion 215_B_i3a extending from the first-second and second-second internal line portions 215_B_i1a and 215_B_i2a and facing the third side surface S3 of the connection region 215_io2a.

The barrier structure 215_B6 may further include an external barrier structure 215_B6_o.

The external barrier structure 215_B6_o may include a first external line portion 215_B6_o1, second external line portions 215_B6_o2, a third external line portion 215_B6_o4a, a fourth external line portion 215_B6_o4b, fifth external portions 216_B6_o3, and sixth external portions 216_B6_o5.

The first external line portion 215_B6_o1 may be between the first-first internal line portion 215_B_i1 and the first-second internal line portion 215_B_i1a, and may extend in the first direction (X-direction). The first external line portion 215_B6_o1 may include a plurality of portions spaced apart from each other in the first direction (X-direction).

The second external line portions 215_B6_o2 may face the second-first internal line portion 215_B_i2. Each of the second external line portions 215_B6_o2 may extend in the first direction (X-direction). The second external line portions 215_B6_o2 may be in parallel with each other. The second external line portions 215_B6_o2 may include a plurality of portions spaced apart from each other in the first direction (X-direction).

The third external line portion 215_B6_o4a may face the second-second internal line portion 215_B_i2a. The third external line portion 215_B6_o4a may extend in the first direction (X-direction). The third external line portion 215_B6_o4a may include a plurality of portions spaced apart from each other in the first direction (X-direction).

The fourth external line portion 215_B6_o4b may face the third external line portion 215_B6_o4a. The fourth external line portion 215_B6_o4b may extend in the first direction (X-direction).

The fifth external portions 216_B6_o3 may have end portions facing the third-1 internal portion 215_B_i3. Each of the fifth external portions 216_B6_o3 may extend in the first direction (X-direction). The fifth external portions 216_B6_o3 may be in parallel with each other.

The sixth external portions 216_B6_o5 may have end portions facing the third-second internal portions 215_B_i3a. Each of the sixth external portions 216_B6_o5 may extend in the first direction (X-direction). The sixth external portions 216_B6_o5 may be in parallel with each other.

The barrier structure 215_B6 may further include connecting portions 215_B6_c. In the same shape as in FIG. 10, the connecting portions 215_B6_c may connect the first internal barrier structure 215_B_i and the external barrier structure 215_B6_o adjacent to each other, and may connect the second internal barrier structure 215_B_ia and the external barrier structure 215_B6_o adjacent to each other.

Next, referring to FIG. 11, among the upper conductive patterns 215 described above, a power interconnection line 215_p and an input/output interconnection line 215_io3 adjacent to each other will be described. FIG. 11 is a partially enlarged plan view illustrating a portion of a semiconductor device according to example embodiments of the present disclosure.

In one example, referring to FIG. 11, the power interconnection line 215_p and the input/output interconnection line 215_io3 may be in parallel with each other. The power interconnection line 215_p may be connected to the plurality of upper conductive vias 210p, and the input/output interconnection line 215_io3 may be connected to a plurality of upper conductive vias 210io. A width of the power interconnection line 215_p may be larger than a width of the input/output interconnection line 210_io3.

The barrier structure 215_B7 may include a first internal barrier line 215_B7_i1 and a second internal barrier line 215_B7_i2 disposed between the power interconnection line 215_p and the input/output interconnection line 215_io3 and in parallel with each other. The barrier structure 215_B7 may further include an external barrier line 215_B7_o disposed on an opposite side of the first internal barrier line 215_B7_i1 with the input/output interconnection line 210_io3 interposed therebetween.

The first internal barrier line 215_B7_i1 may be adjacent to the input/output interconnection line 215_io3, and the second internal barrier line 215_B7_i2 may be adjacent to the power interconnection line 215_p.

A width of the second internal barrier line 215_B7_i2 may be greater than a width of the first internal barrier line 215_B7_i1.

A distance between the second internal barrier line 215_B7_i2 and the power interconnection line 215_p may be greater than a distance between the first internal barrier line 215_B7_i1 and the input/output interconnection line 215_io3.

A distance between the second internal barrier line 215_B7_i2 and the power interconnection line 215_p may be greater than a distance between the first internal barrier line 215_B7_i1 and the second internal barrier line 215_B7_i2.

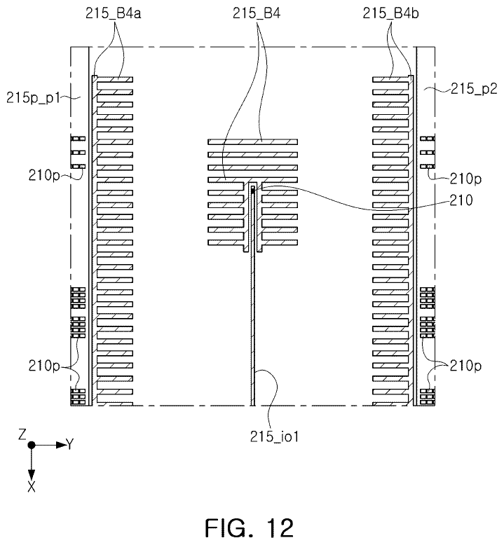

Next, referring to FIG. 12, among the upper conductive patterns 215 described above, a first power interconnection line 215_p1, a second power interconnection line 215_p2, and one input/output interconnection line 215_io1 will be described. FIG. 12A is a partially enlarged plan view illustrating a portion of a semiconductor device according to embodiments of the present invention.

Referring to FIG. 12, an input/output interconnection line 215_io1 may be disposed between a first power interconnection line 215_p1 and a second power interconnection line 215_p2 in parallel with each other.

Each of the first and second power interconnection lines 215_p1 and 215p2 may be connected to the plurality of upper conductive vias 210p. The input/output interconnection line 215_io1 may be connected to an upper conductive via 210.

The barrier structures 215_B4, 215_B4a and 215_B4b may include a first barrier structure 215_B4 adjacent to the input/output interconnection line 215_io1 disposed between the first and second power interconnection lines 215_p1 and 215p2, a second barrier structure 215_B4a adjacent to the first power interconnection line 215_p1 between the first power interconnection line 215_p1 and the input/output interconnection line 215_io1, and a third barrier structure 215_B4b adjacent to the second power interconnection line 215_p2 between the second power interconnection line 215_p2 and the input/output interconnection line 215_io1.

The input/output interconnection line 215_io1 and the first barrier structure 215_B4 may be an input/output interconnection line and a barrier structure of one of the above-described example embodiments. Here, as an example, the input/output interconnection line 215_io1 and the first barrier structure 215_B4 may be substantially the same as those described in FIG. 9D.

The second barrier structure 215_B4a may include a first-first internal barrier line adjacent to the first power interconnection line 215_p1 and extending in the first direction (X-direction), and a plurality of first-first external barrier lines extending from the first-first internal barrier line in a direction oriented toward the second power interconnection line 215_p2.

The third barrier structure 215_B4b may include a first-second internal barrier line adjacent to the second power interconnection line 215_p2 and extending in the first direction (X-direction), and a plurality of first-second external barrier lines extending from the first-second internal barrier line in a direction oriented toward the first power interconnection line 215_p1.

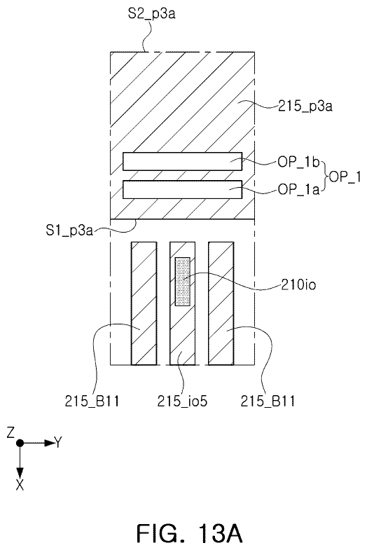

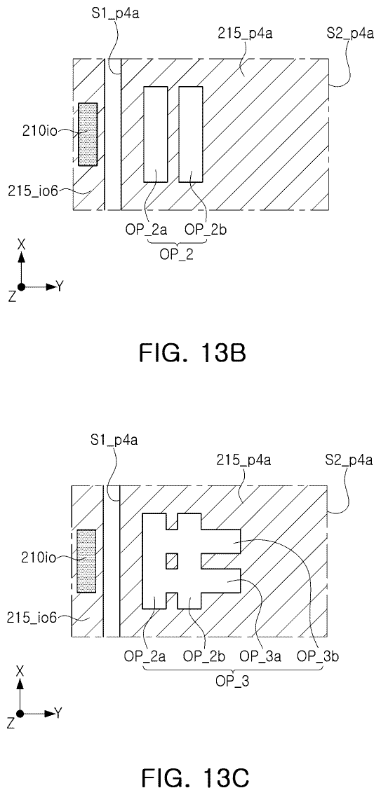

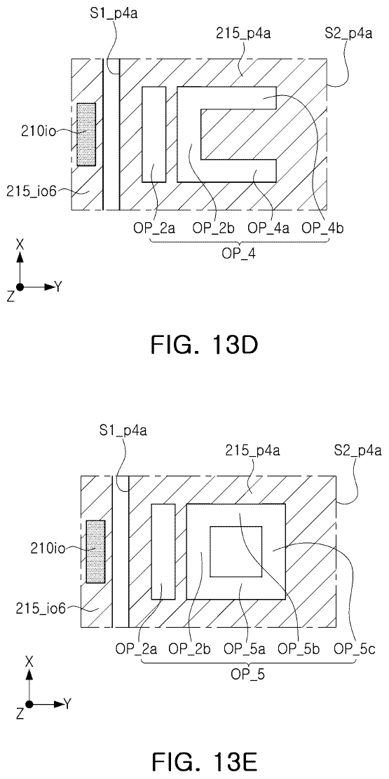

Next, referring to FIGS. 13A to 13E, respectively, among the above-described upper conductive patterns 215, one power interconnection line 215_p and one input/output interconnection line 215_io3 adjacent to each other will be mainly described. FIGS. 13A to 13E are partially enlarged plan views illustrating a portion of a semiconductor device according to example embodiments of the present disclosure.

In one example, referring to FIG. 13A, a power interconnection line 215_p3a may have a first side surface S1_p3a and a second side surface S2_p3a opposing each other. An input/output interconnection line 215_io5 may have a linear shape extending in the first direction (X-direction). An end of the input/output interconnection line 215_io5 may oppose the first side surface S1_p3a. The input/output interconnection line 215_io5 may be connected to an upper conductive via 210io in a region adjacent to the power interconnection line 215_p3a.

Barrier lines 215_B11 having ends facing the power interconnection line 215_p3a may be disposed on both sides of the input/output interconnection line 215_io5.

The power interconnection line 215_p3a may have at least one opening OP_1 in a region adjacent to the input/output interconnection line 215_io5. The at least one opening OP_1 may include first and second openings OP_1a and OP_1b in parallel with each other. Each of the first and second openings OP_1a and OP_1b may have a linear shape extending in the second direction (Y-direction). In plan view, a portion of the input/output interconnection line 215_io5 connected to the upper conductive via 210io and the at least one opening OP_1 may be sequentially arranged in the first direction (X-direction), perpendicular to the first side surface S1_p3a (e.g., the first side surface S1_p3a is between the upper conductive via 210io and the at least one opening OP1). The at least one opening OP_1 may be disposed closer to the first side surface S1_p3a than the second side surface S2_p3a. The first and second openings OP_1a and OP_1b may be sequentially arranged in a direction away from the input/output interconnection line 215_io5.

In an example, referring to FIG. 13B, the power interconnection line 215_p4a may have a first side surface S1_p4a and a second side surface S2_p4a opposing each other. The input/output interconnection line 215_io6 may have a linear shape extending in the first direction (X-direction). A side surface of the input/output interconnection line 215_io5 may oppose the first side surface S1_p4a. The input/output interconnection line 215_io6 may be connected to the upper conductive via 210io in a region adjacent to the power interconnection line 215_p4a.

The power interconnection line 215_p3a may have at least one opening OP_2 in a region adjacent to the input/output interconnection line 215_io5. The at least one opening OP_2 may include first and second openings OP_2a and OP_2b in parallel with each other. Each of the first and second openings OP_2a and OP_2b may have a linear shape extending in the first direction (X-direction). The at least one opening OP_2 may be disposed closer to the first side surface S1_p4a than the second side surface S2_p4a. The first and second openings OP_2a and OP_2b may be sequentially arranged in a direction away from the input/output interconnection line 215_io6.

In an example, referring to FIG. 13C, the at least one opening OP_2 described in FIG. 13B may be replaced with at least one opening OP_3 including the first and second openings OP_2a and OP_2b, and third and fourth openings OP_3a and OP_3b extending from the first opening OP_2a in a direction away from the input/output interconnection line 215_io6 and intersecting the second opening OP_2b.

In an example, referring to FIG. 13D, the at least one opening OP_2 described in FIG. 13B may be replaced with at least one opening OP_4 including the first and second openings OP_2a and OP_2b, and third and fourth openings OP_4a and OP_4b extending from the second opening OP_2b in a direction away from the input/output interconnection line 215_io6.

In an example, referring to FIG. 13E, the at least one opening OP_2 described in FIG. 13B may be replaced with at least one opening OP_5 including the first and second openings OP_2a and OP_2b, the third and fourth openings OP_5a and OP_5b extending from the second opening OP_2b in a direction away from the input/output interconnection line 215_io6, and a fifth opening OP_5c connecting ends of the third and fourth openings OP_5a and OP_5b.

The second opening OP_2b and the fifth opening OP_5c may be in parallel with each other, and the third and fourth openings OP_5a and OP_5b may be in parallel with each other. Accordingly, the second opening OP_2b, the fifth opening OP_5c, and the third and fourth openings OP_5a and OP_5b may have a rectangular ring shape.

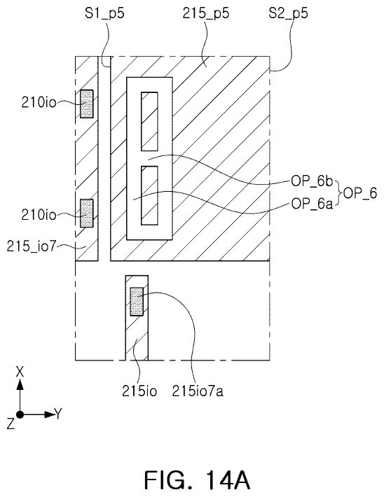

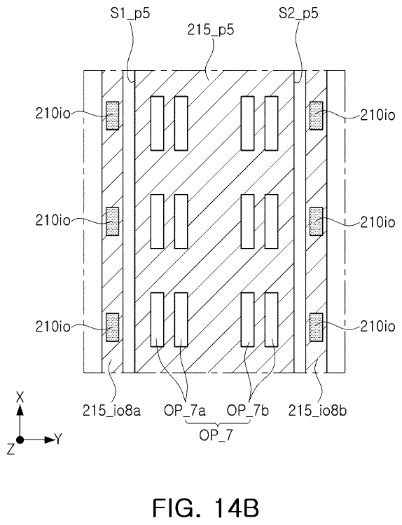

Next, among the upper conductive patterns 215 described above, referring to FIGS. 14A and 14B, respectively, one power interconnection line and a plurality of second input/output interconnection lines adjacent to the one power interconnection line will be mainly described. FIGS. 14A and 14B are partially enlarged plan views illustrating a portion of a semiconductor device according to example embodiments of the present disclosure.

In one example, referring to FIG. 14A, a power interconnection line 215_p5 may have a first side surface S1_p5 and a second side surface S2_p5 opposing each other.

The first input/output interconnection line 215_io7 may have a linear shape extending in the first direction (X-direction). A side surface of the first input/output interconnection line 215_io7 may oppose the first side surface S1_p5. The first input/output interconnection line 215_io7 may be connected to an upper conductive via 210io in a region adjacent to the power interconnection line 215_p5.

The second input/output interconnection line 215_io7a may have a linear shape extending in the first direction (X-direction). An end of the second input/output interconnection line 215_io7a may face the power interconnection line 215_p5. The second input/output interconnection line 215_io7a may be connected to an upper conductive via 210io in a region adjacent to the power interconnection line 215_p5.

The power interconnection line 215_p5 may have at least one opening OP_6 in a region adjacent to the first and second input/output interconnection lines 215_io7 and 215_io7a.

The at least one opening OP_6 may include a rectangular ring-shaped first opening OP_6a including openings extending in the first direction (X-direction) and in parallel with each other and openings extending in the second direction (Y-direction), and a second opening OP_6b connecting the openings in parallel with each. The first opening OP_6a may have a rectangular ring shape elongated in the first direction (X-direction).

In an example, referring to FIG. 14B, the power interconnection line 215_p5 may have a first side surface S1_p5 and a second side surface S2_p5 opposing each other.

The first input/output interconnection line 215_io8a may have a linear shape extending in the first direction (X-direction). A side surface of the first input/output interconnection line 215_io8a may oppose the first side surface S1_p5. The first input/output interconnection line 215_io8a may be connected to an upper conductive via 210io in a region adjacent to the power interconnection line 215_p5.

The second input/output interconnection line 215_io8b may have a linear shape extending in the first direction (X-direction). A side surface of the second input/output interconnection line 215_io8b may oppose the second side surface S2_p5. The second input/output interconnection line 215_io8b may be connected to an upper conductive via 210io in a region adjacent to the power interconnection line 215_p5.

The power interconnection line 215_p5 may have openings OP_7 in a region adjacent to the first and second input/output interconnection lines 215_io7 and 215_io7a.

The openings OP_7 may include the first openings OP_7a extending in the first direction (X-direction) and in parallel with each other, and disposed adjacent to the first input/output interconnection line 215_io8a, and the second openings OP_7b extending in the first direction (X-direction) and in parallel with each other, and disposed adjacent to the second input/output interconnection line 215_io8b.

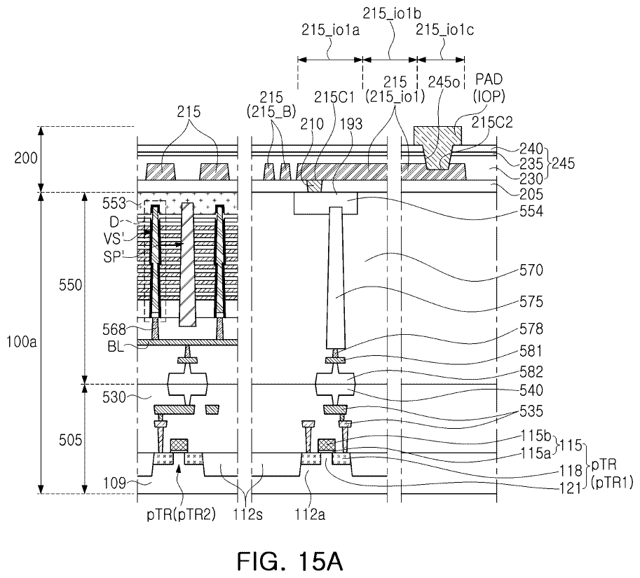

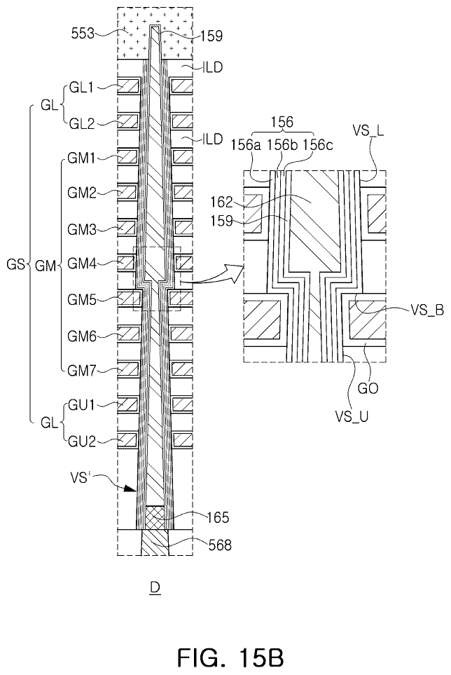

Next, a modified example of the lower structure 100 described with reference to FIGS. 5A and 5B will be described with reference to FIGS. 15A and 15B. FIG. 15A is a cross-sectional view illustrating an example of the semiconductor device CH, and FIG. 15B is a partially enlarged view illustrating a region indicated by ‘D’ in FIG. 15A.

Referring to FIGS. 15A and 15B, the lower structure 100 described with reference to FIGS. 5A and 5B may be replaced with a lower structure 100a illustrated in FIGS. 15A and 15B.

The lower structure 100a may include a peripheral region 505 and a memory region 550 vertically overlapping the peripheral region 505.

The peripheral region 505 may include the substrate 109 as described in FIG. 5A, the peripheral active regions 112a on the substrate 109, and a peripheral element separation region 112s defining the peripheral active regions 112a on the substrate 109. The substrate 109 may be a semiconductor substrate.

The peripheral region 505 may further include a peripheral circuit PTR, a peripheral interconnection structure 535, lower bonding pads 540, and an insulating structure 530 on the substrate 109. The peripheral circuit PTR may include the peripheral transistors pTR1 and pTR2 as described in FIG. 5A.

The memory region 550 may include a source structure 553 and a gate stack structure GS disposed below the source structure 553.

The gate stack structure GS may include a plurality of gate electrodes GL, GM and GU spaced apart from each other in a vertical direction.

The plurality of gate electrodes GL, GM and GU may include one or a plurality of lower gate electrodes GL disposed below the source structure 553, a plurality of intermediate gate electrodes GM disposed below the one or plurality of lower gate electrodes GL, and one or plurality of upper gate electrodes GU disposed below the plurality of intermediate gate electrodes GM.

The one or more lower gate electrodes GL may include a first lower gate electrode GL1 and a second lower gate electrode GL2 below the first lower gate electrode GL1. The first and second lower gate electrodes GL1 and GL2 may function to correspond to the first and second lower gate lines LL1 and LL2 of FIG. 4 described above.

The plurality of intermediate gate electrodes GM may include the word lines WL of FIG. 4 described above. Accordingly, the plurality of intermediate gate electrodes GM may be referred to as word lines. The plurality of intermediate gate electrodes GM may include first to seventh intermediate gate electrodes GM1 to GM7.

The one or more upper gate electrodes GU may include a first upper gate electrode GU1 and a second upper gate electrode GU2 below the first upper gate electrode GU1. The first and second upper gate electrodes GU1 and GU2 may function to correspond to the first and second upper gate lines UL1 and UL2 of FIG. 4 described above.

In example embodiments, the number of the plurality of gate electrodes GL, GM and GU illustrated in the drawings, for example, the number of the plurality of gate electrodes GL, GM and GU may be different from the number illustrated in the drawings.

The memory region 550 may further include interlayer insulating layers ILD alternately and repeatedly stacked with the plurality of gate electrodes GL, GM and GU. Among the plurality of gate electrodes GL, GM and GU and the interlayer insulating layers ILD, an uppermost layer and a lowermost layer may be disposed with the interlayer insulating layers.

The memory region 550 may further include a separation pattern SP′ penetrating through or extending into the plurality of gate electrodes GL, GM and GU and the interlayer insulating layers ILD. The separation pattern SP′ may penetrate through or extend into the plurality of gate electrodes GL, GM and GU to divide the plurality of gate electrodes GL, GM and GU. The memory region 550 may further include a dielectric layer GO configured to cover or overlap upper surfaces, side surfaces, and lower surfaces of each of the plurality of gate electrodes GL, GM and GU.

The memory region 550 may further include vertical memory structures VS′. The vertical memory structures VS' may vertically penetrate through or extend into the gate electrode structures GSs and the interlayer insulating layers ILD.

Each of the vertical memory structures VS' may include an insulating core region 162, a channel layer 159 on a side surface of the insulating core region 162, an information storage structure 156 on an external surface of the channel layer 159, and a pad layer 165 disposed below the insulating core region 162 and in contact with the channel layer 159. The channel layer 159 may cover or overlap a side surface of the insulating core region 162, and may extend between the core region 162 and the source structure 553. The channel layer 159 may include a semiconductor material such as silicon or the like. The data storage structure 156 may include a first dielectric layer 156a, a second dielectric layer 156c, and an information storage layer 156b between the first dielectric layer 156c and the second dielectric layer 156a.

Each of the vertical memory structures VS' may include a lower vertical portion VS_L, an upper vertical portion VS_U below the lower vertical part VS_L, and a bonding portion VS_B between the lower vertical part VS_L and the upper vertical part VS_U.

At least a portion of the source structure 153 may include a silicon layer having an N-type conductivity type. The source structure 153 may include a polysilicon and a metal layer.

The memory region 550 may further include an insulating structure 570 disposed outside and below the gate stack structure GS.

The memory region 550 may further include the bit line BL described above. The bit line BL may be disposed below the gate stack structure GS.

The memory region 550 may further include bit line contact plugs 568 disposed between the bit line BL and the vertical memory structures VS' and electrically connecting the bit line BL to the vertical memory structures VS′.

The memory region 550 may be disposed on the same level as that of at least a portion of the source structure 553, and may further include a conductive connection pattern 554 including a conductive material.

The memory region 550 may include an upper bonding pad 582 bonded to and electrically connected to the lower bonding pad 540, and contact structures 581, 578 and 575 electrically connecting the upper bonding pad 582 to the conductive connection pattern 554 between the upper bonding pad 582 and the conductive connection pattern 554. The contact structures 581, 578 and 575 may include at least two contact plugs 575 and 578 disposed on different levels and at least one interconnection line 581. In the upper structure 200 described above, the upper conductive via 210 may be electrically connected to the conductive connection pattern 554. The upper structure 200 may be the same as the upper structure of one of the above-described example embodiments.

Example embodiments of the technical concept of the present disclosure are to provide a semiconductor device that may improve reliability and durability between an input/output interconnection line and upper conductive via in contact with each other, and a data storage system including the same.

According to example embodiments, a barrier structure may be disposed around an input/output interconnection line and an upper conductive vias in contact with each other. Such a barrier structure may increase reliability and durability between the input/output interconnection line and the upper conductive via in contact with each other. Accordingly, the performance of the semiconductor device may be improved.

According to example embodiments of the technical concept of the present disclosure, in order to improve reliability and durability between the input/output interconnection line and the upper conductive via in contact with each other, a power interconnection line adjacent to the input/output interconnection line may include at least one opening.

Advantages and effects of the present application are not limited to the foregoing content and may be more easily understood in the process of describing a specific example embodiment of the present disclosure.

Although example embodiments of the present disclosure have been described with reference to the accompanying drawings, it will be understood by those skilled in the art that the present disclosure may be implemented in other specific forms without changing its technical concepts or essential features. Therefore, it should be understood that the example embodiments described above are examples and not limited in all respects.

What is claimed is:

1. A semiconductor device, comprising:
a lower structure comprising a memory region that comprises memory cells and a peripheral region that comprises a peripheral circuit; and
an upper structure on the lower structure,
wherein the upper structure comprises:
an inter-metal insulating layer on the lower structure;
a first upper conductive via that extends into the inter-metal insulating layer;
upper conductive patterns on the inter-metal insulating layer; and
a capping insulating structure on the inter-metal insulating layer and the upper conductive patterns,
wherein the upper conductive patterns comprise:
a first input/output interconnection line that is on the inter-metal insulating layer and is in contact with an upper surface of the first upper conductive via; and
a first barrier structure that is on the inter-metal insulating layer and is electrically insulated from the first upper conductive via and the first input/output interconnection line,
wherein the first input/output interconnection line comprises:
a first connection region that is adjacent to the first barrier structure, has a line shape that extends in a first direction that is parallel to an upper surface of the upper structure, and is in contact with the upper surface of the first upper conductive via;
a first interconnection line region that extends from the first connection region; and
a first pad region that extends from the first interconnection line region,
wherein, in plan view, the first connection region comprises a first side surface, a second side surface that opposes the first side surface in a second direction that is perpendicular to the first direction, and a third side surface that extends from respective ends of the first side surface and the second side surface,
wherein the first barrier structure comprises:
a first internal barrier structure adjacent to the first connection region; and
an external barrier structure that is adjacent to the first internal barrier structure and comprises at least two external line portions that are parallel with each other, and
wherein the first internal barrier structure comprises:
a first internal line portion that faces the first side surface of the first connection region;
a second internal line portion that faces the second side surface of the first connection region; and
a third internal portion that extends from the first internal line portion and the second internal line portion and faces the third side surface of the first connection region.

2. The semiconductor device of claim 1, wherein the capping insulating structure comprises a pad opening that exposes at least a portion of the first pad region.

3. The semiconductor device of claim 1, further comprising:
an input/output pad that extends into the capping insulation structure and is connected to at least a portion of the first pad region.

4. The semiconductor device of claim 1, wherein:
the first upper conductive via has a first length in the first direction, and
in the first connection region, a distance in the first direction between a portion in contact with the first upper conductive via and the first interconnection line region is at least twice the first length in the first direction.

5. The semiconductor device of claim 1, wherein the external barrier structure includes:
a first external line portion that is adjacent to the first internal line portion and is parallel with the first internal line portion;
a second external line portion that is adjacent to the second internal line portion and is parallel with the second internal line portion; and
a third external portion that faces the third internal portion.

6. The semiconductor device of claim 5, wherein the third external portion extends from respective ends of the first external line portion and the second external line portion.

7. The semiconductor device of claim 5, wherein the external barrier structure further comprises:
First connection portions that electrically connect the first internal line portion and the first external line portion and are spaced apart from each other in the first direction; and
second connection portions that electrically connect the second internal line portion and the second external line portion and are spaced apart from each other in the first direction.

8. The semiconductor device of claim 1, wherein the external barrier structure further comprises:
first external line portions extending from the first internal line portion in a direction away from the first connection region; and
second external line portions extending from the second internal line portion in a direction away from the first connection region.

9. The semiconductor device of claim 1, wherein a width of the third internal portion in the second direction is different from a width of each of the first internal line portion and the second internal line portion in the first direction.

10. The semiconductor device of claim 1, wherein a width of the third internal portion in the second direction is greater than a width of each of the first internal line portion and the second internal line portion in the first direction.

11. The semiconductor device of claim 1, wherein the first connection region comprises:
a first portion that is adjacent to the first interconnection line region and has a width in the second direction that is the same as a width of the first interconnection line region in the second direction; and
a second portion that extends from the first portion, is electrically connected to the first upper conductive via, and has a width in the second direction that is greater than the width of the first portion in the second direction.

12. The semiconductor device of claim 1, wherein the upper structure further comprises a second upper conductive via that extends into the inter-metal insulating layer, and
the upper conductive patterns further comprise a second input/output interconnection line that is on the inter-metal insulating layer and is in contact with an upper surface of the second upper conductive via,
wherein the second input/output interconnection line comprises:
a second connection region that is adjacent to the first barrier structure, has a line shape that extends in the first direction, and is in contact with the upper surface of the second upper conductive via; and
a second interconnection line region that extends from the second connection region,
wherein, in the plan view, the second connection region comprises a fourth side surface, a fifth side surface that opposes the fourth side surface in the second direction, and a sixth side surface that extends from respective ends of the fourth side surface and the fifth side surface, and
wherein the first barrier structure further comprises a second internal barrier structure adjacent to the second connection region.

13. The semiconductor device of claim 12, wherein the second internal barrier structure comprises:
a third internal line portion that faces the third side surface of the second connection region;
a fourth internal line portion that faces the fourth side surface of the second connection region; and
a fifth internal portion that extends from the third internal line portion and the fourth internal line portion and faces the fifth side surface of the second connection region,
wherein the first internal line portion and the fourth internal line portion are parallel with each other and face each other, and
wherein the external barrier structure comprises:
a first external line portion between the first internal line portion and the fourth internal line portion;
a second external line portion that is adjacent to the second internal line portion and is parallel with the second internal line portion;
a third external line portion that is adjacent to the third internal line portion and is parallel with the third internal line portion;
a sixth internal portion that faces the third internal portion; and
a seventh internal portion that faces the fifth internal portion.

14. The semiconductor device of claim 13, wherein the external barrier structure further comprises connection portions that connect the first internal line portion and the first external line portion and connect the fourth internal line portion and the first external line portion.

15. The semiconductor device of claim 1, wherein the upper conductive patterns further comprise:
a first power interconnection line that is parallel with the first input/output interconnection line; and
a second barrier structure that is adjacent to the first power interconnection line and is spaced apart from the first barrier structure in the second direction,
wherein the second barrier structure comprises a plurality of line portions that are parallel with each other.

16. The semiconductor device of claim 1, wherein each of the upper conductive patterns comprises an adhesion layer, an aluminum layer on the adhesion layer, and a capping conductive layer on the aluminum layer, and
wherein at least a portion of the adhesion layer of the first barrier structure comprises a metal oxide.

17. A semiconductor device, comprising:
a lower structure comprising a memory region that comprises memory cells and a peripheral region that comprises a peripheral circuit; and
an upper structure on the lower structure,
wherein the upper structure comprises:
an inter-metal insulating layer on the lower structure;
a first upper conductive via that extends into the inter-metal insulating layer;
upper conductive patterns on the inter-metal insulating layer; and
a capping insulating structure on the inter-metal insulating layer and the upper conductive patterns,
wherein the upper conductive patterns comprise:
a first input/output interconnection line that is on the inter-metal insulating layer and is in contact with an upper surface of the first upper conductive via; and
a power interconnection line that is on the inter-metal insulating layer and is adjacent to the first input/output interconnection line,
wherein the power interconnection line comprises a first side surface that faces the first input/output interconnection line, a second side surface that faces the first side surface, and at least one opening that is adjacent to the first side surface, and
wherein, in plan view, the first side surface is between a portion of the first input/output interconnection line electrically connected to the first upper conductive via and wherein the at least one opening are sequentially arranged in a first direction that is perpendicular to the first side surface.

18. The semiconductor device of claim 17, wherein the at least one opening comprises a first opening and a second opening sequentially arranged in a direction away from the first input/output interconnection line.

19. A data storage system, comprising:
a semiconductor device comprising an input/output pad; and
a controller electrically connected to the semiconductor device through the input/output pad and configured to control the semiconductor device,
wherein the semiconductor device comprises:
a lower structure comprising a memory region that comprises memory cells and a peripheral region that comprises a peripheral circuit; and
an upper structure on the lower structure,
wherein the upper structure comprises:
an inter-metal insulating layer on the lower structure;
a first upper conductive via that extends into the inter-metal insulating layer;
upper conductive patterns on the inter-metal insulating layer; and
a capping insulating structure on the inter-metal insulating layer and the upper conductive patterns,
wherein the upper conductive patterns comprise:
a first input/output interconnection line that is on the inter-metal insulating layer and is in contact with an upper surface of the first upper conductive via; and
a first barrier structure that is on the inter-metal insulating layer and is electrically insulated from the first upper conductive via and the first input/output interconnection line,
wherein the first input/output interconnection line that comprises:
a first connection region that is adjacent to the first barrier structure, has a line shape that extends in a first direction that is parallel to an upper surface of the upper structure, and is in contact with the upper surface of the first upper conductive via; and
a first interconnection line region that extends from the first connection region,
wherein, in plan view, the first connection region comprises a first side surface, a second side surface that opposes the first side surface in a second direction that is perpendicular to the first direction, and a third side surface that extends from respective ends of the first side surface and the second side surface,
wherein the first barrier structure comprises:
a first internal barrier structure adjacent to the first connection region; and
an external barrier structure that is adjacent to the first internal barrier structure and comprises at least two external line portions that are parallel with each other,
wherein the first internal barrier structure comprises:
a first internal line portion that faces the first side surface of the first connection region;
a second internal line portion that faces the second side surface of the first connection region; and
a third internal portion that extends from the first internal line portion and the second internal line portion and faces the third side surface of the first connection region.

20. The data storage system of claim 19, wherein the upper structure further comprises a second upper conductive via that extends into the inter-metal insulating layer,
wherein the upper conductive patterns comprise:
a second input/output interconnection line electrically connected to the second upper conductive via; and
a power interconnection line adjacent to the second input/output interconnection line,
wherein the power interconnection line comprises a first side surface that faces the second input/output interconnection line, a second side surface that faces the first side surface, and at least one opening that is adjacent to the first side surface,
wherein, in the plan view, the first side surface is between a portion of the second input/output interconnection line that is electrically connected to the second upper conductive via and the at least one opening are sequentially arranged in a direction, perpendicular to the first side surface, and
wherein the at least one opening comprises a first opening and a second opening sequentially arranged in a direction away from the first input/output interconnection line.
